(19) United States
(12) Patent Application Publication
(10) Pub. No.: US 2010/0270146 A1
(43) Pub. Date: Oct. 28, 2010

(54) METHOD FOR MANUFACTURING CO-BASE SINTERED ALLOY SPUTTERING TARGET FOR FORMATION OF MAGNETIC RECORDING FILM WHICH IS LESS LIKELY TO GENERATE PARTRICLES, AND CO-BASE SINTERED ALLOY SPUTTERING TARGET FOR FORMATION OF MAGNETIC RECORDING FILM

(75) Inventors: Sohei Nonaka, Sanda-shi (JP); Yoshinori Shirai, Sanda-shi (JP); Yukiya Sugiuchi, Sasayama-shi (JP)

Correspondence Address: Leason Ellis LLP, 81 Main Street, Suite 503, White Plains, NY, 10601, US

(73) Assignee: MITSUBISHI MATERIALS CORPORATION, Chiyoda-ku (JP)

(21) Appl. No.: 12/294,691

(22) PCT Filed: Mar. 30, 2007
(86) PCT No.: PCT/JP2007/057223

§ 371 Date: Sep. 26, 2008

(30) Foreign Application Priority Data
Mar. 31, 2006 (JP) 2006-097227
Sep. 8, 2006 (JP) 2006-243688
Mar. 26, 2007 (JP) 2007-078223
Mar. 26, 2007 (JP) 2007-078224
Mar. 26, 2007 (JP) 2007-078248

(51) Int. Cl. C23C 14/34; B22F 3/12; B22F 3/15

(52) U.S. Cl. 204/298.13; 419/19

(57) ABSTRACT

A method for manufacturing a Co-base sintered alloy sputtering target for the formation of a magnetic recording film including providing a Cr—Co alloy powder consisting of 50 to 70 atomic % of Cr and remaining Co, a Pt powder, a non-magnetic oxide powder, and a Co powder, blending and mixing the powders together so as to give the chemical composition consisting of 2 to 15 mol % of a non-magnetic oxide, 3 to 20 mol % of Cr, and 5 to 30 mol % of Pt and a remainder containing Co, and sintering the mixture under pressure. Or alternatively providing a Pt—Cr binary alloy powder consisting of 10 to 90 atomic % of Pt and remaining Cr, a Pt powder, a non-magnetic oxide powder, and a Co powder, blending and mixing the powders so as to give the chemical composition above, and then sintering the mixture under pressure.

### CROSS REFERENCE TO PRIOR RELATED APPLICATIONS

This is a U.S. national phase application under 35 U.S.C. §371 of International Patent Application No. PCT/JP2007/057223 filed Mar. 30, 2007 and claims the benefit of Japanese Application No. 2006-097227, filed Mar. 31, 2006; Japanese Application No. 2006-243688, filed Sep. 8, 2006; Japanese Application No. 2007-078223, filed Mar. 26, 2007; Japanese Application No. 2007-078224, filed Mar. 26, 2007; and Japanese Application No. 2007-078248, filed Mar. 26, 2007. The contents of these applications are incorporated herein in their entirety. The International Application was published in Japanese on Oct. 18, 2007 as International Publication No. WO/2007/116834 under PCT Article 21(2).

### TECHNICAL FIELD

The present invention relates to a method for manufacturing a sputtering target for the formation of a magnetic recording film that is applied to a high density magnetic recording medium of a hard disk, in particular, a magnetic recording film that is applied to a perpendicular magnetic recording medium; and a sputtering target for the formation of a magnetic recording film.

### BACKGROUND OF THE INVENTION

Hard disk devices are generally used as an external recording device for computers, digital consumer electronics, and the like and there are demands for further improvements in their recording density. Accordingly, in recent years, a perpendicular magnetic recording method that can achieve ultrahigh density recording has been drawing attention. This perpendicular magnetic recording method is said to stabilize the record magnetization in theory as it becomes higher density unlike the conventional longitudinal recording method, and its application for practical use has been started. A CoCrPt—SiO₂ granular magnetic recording film has been proposed as a hopeful candidate for the material to be applied in the magnetic recording layer of a hard disk medium of this perpendicular magnetic recording method, and this magnetic recording film needs to be a high-performance magnetic recording film. A CoCrPt—SiO₂ granular magnetic recording film is proposed as one of the magnetic recording films that can be applied to the above, and this CoCrPt—SiO₂ granular magnetic recording film is known to be produced by a magnetron sputtering method using a Co-base sintered alloy sputtering target that includes a mixed phase of a Co-base sintered alloy phase containing Cr and Pt and a silicon dioxide phase see Fuji Electric Journal: Vol. 75; No. 3; 2002 (pp. 169-172).

It is known that this Co-base sintered alloy sputtering target is usually produced by first blending and mixing a silicon dioxide powder, a Cr powder, a Pt powder, and a Co powder so that a chemical composition consisting of 2 to 15 mol % of silicon dioxide, 3 to 20 mol % of Cr, 5 to 30 mol % of Pt and a remainder containing Co is obtained, and then subjecting the resulting mixed powder to a pressure sintering process employing a hot pressing method, a hot isostatic pressing method, or the like. In the production, a silicon dioxide powder produced by high temperature flame hydrolysis is used as the aforementioned silicon dioxide powder and the silicon dioxide phase dispersed in the microstructure of the target is made to have an extremely fine structure of not larger than 10 μm so as to make the generation of particles less likely (see, for example, Japanese Unexamined Patent Application, First Publication No. 2001-236643; and Japanese Unexamined Patent Application, First Publication No. 2004-339586). Moreover, it is known that non-magnetic oxides such as TiO, Cr₂O₃, TiO₂, Ta₂O₅, Al₂O₃, BeO₂, MgO, ThO₂, ZrO₂, CeO₂, and Y₂O₃ can be used other than the aforementioned SiO₂ (see Japanese Unexamined Patent Application, First Publication No. 2003-36525 and Japanese Unexamined Patent Application, First Publication No. 2006-24346.

However, generation of particles has been unavoidable with the Co-base sintered alloy sputtering target produced by the conventional method described above, and thus a sputtering target formed of a Co-base sintered alloy which is even less likely to generate particles has been required.

### SUMMARY OF THE INVENTION

The present inventors conducted extensive and intensive studies in order to achieve a Co-base sintered alloy sputtering target which is even less likely to generate particles and discovered the following:

(i) one of the causes for the generation of particles is the dispersion of coarse aggregates or precipitates having Cr and O as main components (hereinafter referred to as chromium oxide aggregates) which have an absolute maximum length (maximum value of the distance between the two arbitrary points on the periphery of the particle) of more than 10 μm in the microstructure of the target; and
(ii) in order to avoid the presence of these coarse chromium oxide aggregates in the microstructure, it is preferable to use an alloy powder having an intermetallic compound of Cr and Co, which has a chemical composition consisting of 50 to 70 atomic % of Cr and a remainder containing Co as a main component (hereinafter referred to as a Cr—Co alloy powder) as a raw material powder instead of a Cr powder.

A first aspect of the present invention is made based on such findings and characterized by the following:

(1) A method for manufacturing a Co-base sintered alloy sputtering target for formation of a magnetic recording film which is less likely to generate particles, the method including: providing, as raw material powders, a Cr—Co alloy powder consisting of 50 to 70 atomic % of Cr and a remainder containing Co, a Pt powder, a non-magnetic oxide powder, and a Co powder; blending and mixing the raw material powders together so as to give a chemical composition consisting of 2 to 15 mol % of a nonmagnetic oxide, 3 to 20 mol % of Cr, and 5 to 30 mol % of Pt and a remainder containing Co; and thereafter subjecting the resulting mixed powder to a pressure sintering process;
(2) The method for manufacturing a Co-base sintered alloy sputtering target for the formation of a magnetic recording film which is less likely to generate particles according to item (1) above, wherein the non-magnetic oxide is any one of silicon dioxide, tantalum oxide, titanium oxide, aluminum oxide, magnesium oxide, thorium oxide, zirconium oxide, cerium oxide, and yttrium oxide;
(3) The method for manufacturing a Co-base sintered alloy sputtering target for the formation of a magnetic recording film which is less likely to generate particles according to item (1) above, wherein the pressure sintering process is a hot pressing process or a hot isostatic pressing process; and
(4) A Co-base sintered alloy sputtering target for formation of a magnetic recording film which is less likely to generate particles manufactured by any one of the methods of items (1), (2), and (3) above.

In addition, the present inventors conducted a further study in order to achieve a Co-base sintered alloy sputtering target which is even less likely to generate particles and discovered the following:

(iii) one of the causes for the generation of particles is the dispersion of coarse aggregates or precipitates having Cr and O as major components (hereinafter referred to as chromium oxide aggregates) which have an absolute maximum length (maximum value of the distance between two arbitrary points on the periphery of the particle) of more than 10 μm in the microstructure of the target;
(iv) in order to avoid the presence of these coarse chromium oxide aggregates in the microstructure, it is preferable to use a binary alloy powder of Pt and Cr (hereinafter referred to as a Pt—Cr binary alloy powder), which has a chemical composition consisting of 10 to 90 atomic % of Pt and a remainder containing Cr, as a raw material powder instead of a Cr powder; and
(v) in order to avoid the presence of these coarse chromium oxide aggregates in the microstructure, it is preferable to use the Pt—Cr binary alloy powder and a binary alloy powder of Cr and Co (hereinafter referred to as a Co—Cr binary alloy powder), which consists of 50 to 70 atomic % of Cr and a remainder containing Co, as raw material powders instead of a Cr powder.

A second aspect of the present invention is made based on such findings and characterized by the following:

(5) A method for manufacturing a Co-base sintered alloy sputtering target for formation of a magnetic recording film which is less likely to generate particles, the method including: providing, as raw material powders, a Cr—Pt binary alloy powder consisting of 10 to 90 atomic % of Pt and a remainder containing Cr, a Pt powder, a non-magnetic oxide powder, and a Co powder; blending and mixing the raw material powders so as to give a chemical composition consisting of 2 to 15 mol % of the non-magnetic oxide, 3 to 20 mol % of Cr, and 5 to 30 mol % of Pt and a remainder containing Co; and thereafter subjecting the resulting mixed powder to a pressure sintering process;
(6) A method for manufacturing a Co-base sintered alloy sputtering target for formation of a magnetic recording film which is less likely to generate particles, the method including: providing, as raw material powders, a Cr—Pt binary alloy powder consisting of 10 to 90 atomic % of Pt and a remainder containing Cr, a Co—Cr binary alloy powder consisting of 50 to 70 atomic % of Cr and a remainder containing Co, a Pt powder, a non-magnetic oxide powder, and a Co powder; blending and mixing the raw material powders so as to give a chemical composition consisting of 2 to 15 mol % of the non-magnetic oxide, 3 to 20 mol % of Cr, and 5 to 30 mol % of Pt and a remainder containing Co; and thereafter subjecting the resulting mixed powder to a pressure sintering process;
(7) A method for manufacturing a Co-base sintered alloy sputtering target for formation of a magnetic recording film which is less likely to generate particles, the method including: providing, as raw material powders, a Cr—Pt binary alloy powder consisting of 10 to 90 atomic % of Pt and a remainder containing Cr, a Co—Cr binary alloy powder consisting of 50 to 70 atomic % of Cr and a remainder containing Co, a non-magnetic oxide powder, and a Co powder; blending and mixing the raw material powders so as to give a chemical composition formed of 2 to 15 mol % of the non-magnetic oxide, 3 to 20 mol % of Cr, 5 to 30 mol % of Pt and a remainder containing Co; and thereafter subjecting the resulting mixed powder to a pressure sintering process;
(8) The method for manufacturing a Co-base sintered alloy sputtering target for the formation of a magnetic recording film which is less likely to generate particles according to any one of items (5), (6), and (7) above, wherein the non-magnetic oxide is any one of silicon dioxide, tantalum oxide, titanium oxide, aluminum oxide, magnesium oxide, thorium oxide, zirconium oxide, cerium oxide, and yttrium oxide;
(9) The method for manufacturing a Co-base sintered alloy sputtering target for the formation of a magnetic recording film which is less likely to generate particles according to any one of items (5), (6), and (7) above, wherein the pressure sintering process is a hot pressing process or a hot isostatic pressing process;
(10) A Co-base sintered alloy sputtering target for formation of a magnetic recording film which is less likely to generate particles manufactured by any one of the methods of items (5), (6), (7), (8), and (9) above which is a Co-base sintered alloy sputtering target for the formation of a magnetic recording film having a chemical composition consisting of 2 to 15 mol % of the non-magnetic oxide, 3 to 20 mol % of Cr, and 5 to 30 mol % of Pt and a remainder containing Co, wherein an absolute maximum length of chromium oxide aggregates dispersed in a microstructure is not more than 10 μm; and
(11) The Co-base sintered alloy sputtering target for the formation of a magnetic recording film which is less likely to generate particles according to item (10) above, wherein the non-magnetic oxide is any one of silicon dioxide, tantalum oxide, titanium oxide, aluminum oxide, magnesium oxide, thorium oxide, zirconium oxide, cerium oxide, and yttrium oxide.

Moreover, the present inventors conducted a further more study in order to achieve a Co-base sintered alloy sputtering target which is even less likely to generate particles and discovered the following:

(vi) since numerous particles are likely to be generated when the number of aggregates or precipitates dispersed in the microstructure of the target which have Cr and O as major components (hereinafter referred to as chromium oxide aggregates) and an absolute maximum length (maximum value of the distance between the two arbitrary points on the periphery of the particle) of more than 5 μm is more than 500 aggregates/mm², it is required that the number of chromium oxide aggregates having an absolute maximum length of more than 5 μm is not more than 500 aggregates/mm²; and
(vii) since particles are likely to be generated when coarse chromium oxide aggregates having an absolute maximum length of more than 10 μm are dispersed in the microstructure of the target even if the number of chromium oxide aggregates having an absolute maximum length of more than 5 μm is not more than 500 aggregates/mm², it is more preferable that the coarse chromium oxide aggregates having an absolute maximum length of more than 10 μm be absent.

A third aspect of the present invention is made based on such findings and characterized by the following:

(12) A Co-base sintered alloy sputtering target for formation of a magnetic recording film which is less likely to generate particles having a composition consisting of 2 to 15 mol % of a non-magnetic oxide, 3 to 20 mol % of Cr, and 5 to 30 mol % of Pt and a remainder containing Co and inevitable impurities, wherein the number of chromium oxide aggregates having an absolute maximum length of more than 5 μm in a microstructure is not more than 500 aggregates/mm²; and
(13) The Co-base sintered alloy sputtering target for the formation of a magnetic recording film which is less likely to generate particles according to item (12) above, wherein chromium oxide aggregates having an absolute maximum length of more than 10 μm are absent in a target microstructure.

The first aspect of the present invention will be described below. The reason for limiting the composition of the Cr—Co alloy powder, which is used in the method for manufacturing a Co-base sintered alloy sputtering target for the formation of a magnetic recording film which is less likely to generate particles according to the first aspect of the present invention, as described above is that when the Cr content is less than 50 atomic % or more than 70 atomic %, the amount of a Co solid solution or Cr solid solution that has a weak bond between Co and Cr increases in the powder apart from the intermetallic compound, and thus it is not preferable since Cr readily forms coarse chromium oxide aggregates by reacting with oxygen or a non-magnetic oxide during mixing or sintering. A more preferable range of the Cr content in the Cr—Co alloy powder is 54 to 67 atomic %.

The reason why chromium oxide aggregates causing the generation of particles is that chromium oxide aggregates are extremely brittle, and thus fall off or cause arcing during sputtering. Moreover, when the size of chromium oxide aggregates is large, they fall off from the target surface during processing of the target and form defects at the parts from which they fall off. The following is considered to be the reason for the suppression of production of chromium oxide aggregates due to the use of the Cr—Co alloy powder as a raw material powder. An intermetallic compound phase is present between Cr and Co when the Cr content is about 54 to 67 atomic %. When Co and Cr are alloyed at about the above composition and all or most Cr is fed in the form of an intermetallic compound with Co, the Cr in the intermetallic compound is bound tightly with Co and is less likely to react with oxygen or a non-magnetic oxide as compared to the case where Cr is present as a simple substance or a solid solution.

With respect to the particle size of the Cr—Co alloy powder used in the method for manufacturing a Co-base sintered alloy sputtering target for the formation of a magnetic recording film which is less likely to generate particles according to the first aspect of the present invention, it is preferable that the particle size of the Cr—Co alloy powder in terms of the 50% particle size be not more than 150 μm since satisfactory grinding cannot be carried out during the mixing/grinding process when the 50% particle size exceeds 150 μm. In addition, as the finer the particle size, the better, it is more preferable to make the 50% particle size 75 μm or less, still more preferably 45 μm or less by a classification process or the like. Moreover, both the Co powder and the Pt powder preferably have a 50% particle size of 50 μm or less (more preferably 50% particle size of 40 μm or less), and the non-magnetic oxide powder has a 50% particle size of 20 μm or less (more preferably 50% particle size of 10 μm or less). The reason for this is that it is difficult to achieve a uniform structure after mixing when the Co powder and the Pt powder have larger particle sizes. In addition, when the non-magnetic oxide powder has a particle size larger than the above-mentioned size, it is likely that large non-magnetic oxides having a size of 10 μm or more becomes present in the target even after conducting a mixing/grinding process, and they will cause arcing during sputtering or particle generation.

The aforementioned mixing of the raw material powders is preferably carried out in an inert gas atmosphere. This is because the above condition will further prevent the formation of chromium oxide aggregates due to the bonding of Cr with oxygen during mixing.

Next, the second aspect of the present invention will be described.

The reason for limiting the composition of the Cr—Pt binary alloy powder, which is used in the method for manufacturing a Co-base sintered alloy sputtering target for the formation of a magnetic recording film which is less likely to generate particles according to the second aspect of the present invention, as described above is that when the Pt content is less than 10 atomic % or more than 90 atomic %, the amount of Cr solid solution that has a weak bond between Pt and Cr increases in the powder apart from the intermetallic compound, and thus it is not preferable since Cr readily forms chromium oxide aggregates by reacting with oxygen or a non-magnetic oxide during mixing or sintering. A more preferable range of the Pt content in the Cr—Pt binary alloy powder is 15 to 25 atomic %. The particle size of the Cr—Pt binary alloy powder used as a raw material powder is preferably 150 μm or less since satisfactory grinding becomes difficult to achieve when the particle size is larger than 150 μm, and it is more preferable to make the particle size 75 μm or less, still more preferably 45 μm or less by a classification process or the like.

In addition, the reason for limiting the composition of the Co—Cr binary alloy powder, which is used in the method for manufacturing a Co-base sintered alloy sputtering target for the formation of a magnetic recording film which is less likely to generate particles according to the second aspect of the present invention, as described above is that when the Cr content is less than 50 atomic % or more than 70 atomic %, the amount of a Co solid solution or Cr solid solution that has a weak bond between Co and Cr increases in the powder apart from the intermetallic compound, and thus it is not preferable since Cr readily forms coarse chromium oxide aggregates by reacting with oxygen or a non-magnetic oxide during mixing or sintering. A more preferable range of the Cr content in the Co—Cr binary alloy powder is 54 to 67 atomic %. The particle size of the Co—Cr binary alloy powder used as a raw material powder is preferably 150 μm or less since satisfactory grinding is difficult to achieve when the particle size is larger than 150 μm, and it is more preferable to make the particle size 75 μm or less, still more preferably 45 μm or less by a classification process or the like.

As mentioned above, the reasons for chromium oxide aggregates causing the generation of particles are that chromium oxide aggregates are extremely brittle, and thus fall off or cause arcing during sputtering, and moreover, when the size of chromium oxide aggregates is large, they fall off from the target surface during processing of the target and form defects at the parts from which they fall off. It is considered that since oxidation due to the reaction with oxygen or a non-magnetic oxide is less likely to occur by using the Cr—Pt binary alloy powder or the Cr—Pt binary alloy powder and the Co—Cr binary alloy powder, in which Cr is alloyed, as raw material powders, the production of chromium oxide aggregates is suppressed, and thus the generation of particles will be less likely.

Moreover, both the Co powder and the Pt powder, which are used in the method for manufacturing a Co-base sintered alloy sputtering target for the formation of a magnetic recording film which is less likely to generate particles according to the second aspect of the present invention, preferably have a 50% particle size of 50 μm or less (more preferably 50% particle size of 40 μm or less), and the non-magnetic oxide powder has a 50% particle size of 20 μm or less (more preferably 50% particle size of 10 μm or less). The reason for this is that it is difficult to achieve a uniform structure after mixing when the Co powder and the Pt powder have larger particle sizes. In addition, when the non-magnetic oxide powder has a particle size larger than the above-mentioned size, it is likely that large non-magnetic oxides having a size of 10 μm or more becomes present in the target even after conducting a mixing/grinding process, and they will cause arcing during sputtering or particle generation. The aforementioned mixing of the raw material powders is preferably carried out in an inert gas atmosphere. This is because the above condition will further prevent the formation of chromium oxide aggregates due to the bonding of Cr with oxygen during mixing.

Next, the third aspect of the present invention will be described.

The reason for limiting the number of chromium oxide aggregates having an absolute maximum length (maximum value of the distance between two arbitrary points on the periphery of the particle) of more than 5 μm, in the microstructure of the Co-base sintered alloy sputtering target for the formation of a magnetic recording film which is less likely to generate particles according to the third aspect of the present invention, being not more than 500 aggregates/mm² is that the chromium oxide aggregates having an absolute maximum length of not more than 5 μm have little effects when falling off or causing arcing during sputtering, and even when the chromium oxide aggregates having an absolute maximum length of more than 5 μm are present, the generation of particles remains at a low level and does not lead to failures in the film formation if the number of aggregates is not more than 500 aggregates/mm².

By using the Cr—Co alloy powder consisting of 50 to 70 atomic % of Cr and a remainder containing Co when manufacturing the Co-base sintered alloy sputtering target for the formation of a magnetic recording film which is less likely to generate particles according to the third aspect of the present invention, it becomes possible to manufacture a Co-base sintered alloy sputtering target for the formation of a magnetic recording film in which the number of chromium oxide aggregates having an absolute maximum length of more than 5 μm being not more than 500 aggregates/mm² The reason for limiting the composition of the Cr—Co alloy powder as described above is that when the Cr content is less than 50 atomic % or more than 70 atomic %, the amount of a Co solid solution or Cr solid solution that has a weak bond between Co and Cr increases in the powder apart from the intermetallic compound, and thus it is not preferable since Cr readily forms coarse chromium oxide aggregates by reacting with oxygen or a non-magnetic oxide during mixing or sintering. A more preferable range of the Cr content in the Cr—Co alloy powder is 54 to 67 atomic %. In addition, similar effects can also be attained by using a Cr—Pt alloy powder or a Cr—Co—Pt alloy powder.

As mentioned above, the reasons for chromium oxide aggregates causing the generation of particles are that chromium oxide aggregates are extremely brittle, and thus fall off or cause arcing during sputtering, and moreover, when the size of chromium oxide aggregates is large, they fall off from the target surface during processing of the target and form defects at parts from which they fall off. The following is considered to be the reason for the suppression of production of chromium oxide aggregates due to the use of the Cr—Co alloy powder as a raw material powder. An intermetallic compound phase is present between Cr and Co when the Cr content is about 54 to 67 atomic %. When Co and Cr are alloyed at about the above composition and all or most Cr is fed in the form of an intermetallic compound with Co, the Cr in the intermetallic compound is tightly bound with Co and is less likely to react with oxygen or a non-magnetic oxide as compared to the case where Cr is present as a simple substance or a solid solution.

With respect to the particle size of the Cr—Co alloy powder used for manufacturing a Co-base sintered alloy sputtering target for the formation of a magnetic recording film which is less likely to generate particles according to the third aspect of the present invention, it is preferable that the particle size of the Cr—Co alloy powder in terms of the 50% particle size be not more than 150 μm since satisfactory grinding cannot be carried out during the mixing/grinding process when the 50% particle size exceeds 150 μm. In addition, as the finer the particle size is, the better, it is more preferable to make the 50% particle size 75 μm or less, still more preferably 45 μm or less by a classification process or the like. Moreover, both the Co powder and the Pt powder preferably have a 50% particle size of 50 μm or less (more preferably 50% particle size of 40 μm or less), and the non-magnetic oxide powder has a 50% particle size of 20 μm or less (more preferably 50% particle size of 10 μm or less). The reason for this is that it is difficult to achieve a uniform structure after mixing when the Co powder and the Pt powder have larger particle sizes. In addition, when the non-magnetic oxide powder has a particle size larger than the above-mentioned size, it is likely that large non-magnetic oxides having a size of 10 μm or more becomes present in the target even after conducting a mixing/grinding process, and they will cause arcing during sputtering or particle generation.

The aforementioned mixing of the raw material powders is preferably carried out in an inert gas atmosphere. This is because the above condition is able to further prevent the formation of chromium oxide aggregates due to the bonding of Cr with oxygen during mixing.

The present invention can provide a sputtering target capable of forming an excellent magnetic recording film that is even less likely to generate particles, and thus can greatly contribute to the progress in the industries of computers, digital consumer electronics, and the like.

### DESCRIPTION OF THE INVENTION

### First Aspect

Co—Cr alloy powders A to J having chemical compositions shown in Table 1 were prepared as raw material powders by a gas atomizing method. Since the Co—Cr alloy powders A to J obtained by the gas atomizing method had a 50% particle size of 95 μm, the Co—Cr alloy powders A to J were classified using a sieve with an aperture size of 45 nm so that the 50% particle size of all the powders measured by a laser diffraction method would be 35 μm. Moreover, a Co powder having a 50% particle size of 10 μm, a Pt powder having a 50% particle size of 15 μm, an SiO₂ powder having a 50% particle size of 3 μm, a TiO₂ powder having a 50% particle size of 3 μm, a Ta₂O₅ powder having a 50% particle size of 3 μm, and a Cr powder having a 50% particle size of 10 μm which were commercially available were prepared.

TABLE 1

| | | | Composition | |
|---|---|---|---|---|
| | | 50% particle | (atomic %) | |
| Type | | size (μm) | Cr | Co |
| Co—Cr | A | 35 | 50 | Remainder |
| alloy | B | | 54 | Remainder |
| powder | C | | 58 | Remainder |
| | D | | 60 | Remainder |
| | E | | 62 | Remainder |
| | F | | 65 | Remainder |
| | G | | 67 | Remainder |
| | H | | 70 | Remainder |
| | I | | 48* | Remainder |
| | J | | 72* | Remainder |

Symbols (*) indicate conditions outside the scope of the present invention.

### Example 1

The raw material powders prepared above were blended so as to give the compositions shown in Table 2 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

Methods 1A to 8A of the present invention, comparative methods 1A and 2A, and a conventional method 1A were conducted as follows. The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies having the compositions shown in Table 2. These hot pressed bodies were cut to produce targets having a diameter of 152.4 mm and a thickness of 3 mm

Absolute maximum lengths (maximum value of the distance between the two arbitrary points on the periphery of the particle) of the chromium oxide aggregates dispersed in the microstructure of the targets produced by the aforementioned methods 1A to 8A of the present invention, the comparative methods 1A and 2A, and the conventional method 1A were measured by an electron probe microanalyzer (EPMA). The presence/absence of coarse chromium oxide aggregates having an absolute maximum length of more than 10 μm is shown in Table 2. Measurements of the absolute maximum length of chromium oxide aggregates using an EPMA were conducted as follows. Samples were cut out from the hot pressed bodies produced by the aforementioned methods 1A to 8A of the present invention, the comparative methods 1A and 2A, and the conventional method 1A and the sections thereof were embedded in a resin to be subjected to a minor polishing process. Surface analysis was conducted on the structures of these sections using a field emission EPMA (JXA-8500F manufactured by JEOL Ltd.) at an acceleration voltage of 15 kV, an irradiation current of 5×10⁻⁸ A, and a magnification of 1,000 to acquire an element mapping image of Cr. This element mapping image of Cr was made to be an image with a contrast and a color tone so that the regions enriched with Cr (that is, chromium oxide aggregates) can be clearly discriminated as much as possible. The obtained element mapping image of Cr was saved as an image file of bitmap format without degrading the image quality and this image was read separately using image processing software (Win Roof manufactured by Mitani Corporation) to binarize the image. Absolute maximum length of the regions enriched with Cr as compared to the matrix was measured by image processing. A threshold value was selected for binarization so that the size of the Cr enriched regions did not change from that of the original image. A scale bar indicated on the original element mapping image of Cr by EPMA was used for the calibration of length during measurements.

Moreover, the targets obtained by the aforementioned methods 1A to 8A of the present invention, the comparative methods 1A and 2A, and the conventional method 1A were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under conditions in which the ultimate vacuum was 5×10⁻⁵ Pa, the electrical power was 800 W in direct current, the Ar gas pressure was 6.0 Pa, the distance between the target and the substrate was 60 mm, and no substrate heating, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 2.

TABLE 2

| | | Composition of raw material powder (% by mass) | | | | | | | | | Presence/absence of Cr | |
|---|---|---|---|---|---|---|---|---|---|---|---|---|
| | | Alloy | | | | | | | | | oxides having absolute | |
| | | powder of | | SiO₂ | | | Composition of target (mol %) | | | | maximum length larger | Number of |
| Type | | Table 1 | Pt powder | powder | Cr powder | Co powder | Cr | Pt | SiO₂ | Co | than 10 μm | particles |
| Method of | 1A | A: 14.9 | 39.3 | 7.5 | — | Remainder | 10.8 | 16.2 | 10.0 | Remainder | Absent | 75 |
| present | 2A | B: 13.7 | | | | Remainder | | | | Remainder | Absent | 52 |
| invention | 3A | C: 12.7 | | | | Remainder | | | | Remainder | Absent | 63 |
| | 4A | D: 12.3 | | | | Remainder | | | | Remainder | Absent | 54 |
| | 5A | E: 11.8 | | | | Remainder | | | | Remainder | Absent | 60 |
| | 6A | F: 11.3 | | | | Remainder | | | | Remainder | Absent | 62 |
| | 7A | G: 10.9 | | | | Remainder | | | | Remainder | Absent | 81 |
| | 8A | H: 10.4 | | | | Remainder | | | | Remainder | Absent | 95 |
| Comparative | 1A | I: 15.6 | | | | Remainder | | | | Remainder | Present | 155 |
| method | 2A | J: 10.1 | | | | Remainder | | | | Remainder | Present | 182 |

| | | | | | | |
|---|---|---|---|---|---|---|
| Conventional | — | 7.0 | Remainder | Remainder | Present | 205 |
| method 1A | | | | | | |

Symbols (*) indicate conditions outside the scope of the present invention.

From the results shown in Table 2, it is apparent that the targets produced by the aforementioned methods 1A to 8A of the present invention which were produced by blending the Co—Cr alloy powders A to H having a Cr content of 50 to 70 atomic % and a remainder containing Co as the raw material powders generated less particles as compared to the target produced by the conventional method 1A which was produced by blending and mixing a Co powder having a 50% particle size of 10 μm, a Cr powder having a 50% particle size of 10 μm, a Pt powder having a 50% particle size of 15 μm, and an SiO₂ powder having a 50% particle size of 3 μm without adding a Co—Cr alloy powder. However, it is apparent that the targets produced by the comparative methods 1A and 2A which were produced using the Co—Cr alloy powders I to J having compositions that were outside the scope of the present invention generated numerous particles, and thus were not preferable.

### Example 2

The raw material powders prepared above were blended so as to give the compositions shown in Table 3 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

The obtained mixed powders were filled in an SUS container and were subjected to a vacuum degassing treatment under conditions in which the powders were retained at a temperature of 550° C. for 12 hours, and thereafter the mixed powders were vacuum encapsulated by sealing the SUS container. Methods 9A to 16A of the present invention, comparative methods 3A and 4A, and a conventional method 2A were conducted as follows. The SUS container filled with the mixed powders was subjected to a hot isostatic pressing process under conditions in which the powders were retained at a temperature of 1,200° C. and a pressure of 100 MPa for 3 hours followed by opening the SUS container to produce hot isostatic pressed bodies having the compositions shown in Table 3. These hot isostatic pressed bodies were cut to produce targets having a diameter of 152.4 mm and a thickness of 3 mm

Absolute maximum lengths (maximum value of the distance between the two arbitrary points on the periphery of the particle) of the chromium oxide aggregates dispersed in the microstructure of the target produced by the aforementioned methods 9A to 16A of the present invention, the comparative methods 3A and 4A, and the conventional method 2A were measured by an EPMA. The presence/absence of coarse chromium oxide aggregates having an absolute maximum length of more than 10 μm is shown in Table 3.

Measurements of the absolute maximum length of chromium oxide aggregates using an EPMA were conducted as follows. Samples were cut out from the targets produced by the aforementioned methods 9A to 16A of the present invention, the comparative methods 3A and 4A, and the conventional method 2A and the sections thereof were embedded in a resin to be subjected to a minor polishing process. Surface analysis was conducted on the structures of these sections using a field emission EPMA (JXA-8500F manufactured by JEOL Ltd.) at an acceleration voltage of 15 kV, an irradiation current of 5×10⁻⁸ A, and a magnification of 1,000× to acquire an element mapping image of Cr. This element mapping image of Cr was made to be an image with a contrast and a color tone so that the regions enriched with Cr (that is, chromium oxide aggregates) can be clearly discriminated as much as possible.

The obtained element mapping image of Cr was saved as an image file of bitmap format without degrading the image quality and this image was read separately using image processing software (Win Roof manufactured by Mitani Corporation) to binarize the image. Absolute maximum lengths of the regions enriched with Cr as compared to the matrix were measured by image processing. A threshold value was selected for binarization so that the size of the Cr enriched regions did not change from that of the original image. A scale bar indicated on the original element mapping image of Cr by EPMA was used for the calibration of length during measurements.

Moreover, the targets obtained by the aforementioned methods 9A to 16A of the present invention, the comparative methods 3A and 4A, and the conventional method 2A were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under conditions in which the ultimate vacuum was 5×10⁻⁵ Pa, the electrical power was 800 W in direct current, the Ar gas pressure was 6.0 Pa, the distance between the target and the substrate was 60 mm, and no substrate heating, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 3.

TABLE 3

| | | Composition of raw material powder (% by mass) | | | | | | | | | Presence/absence of Cr | |
|---|---|---|---|---|---|---|---|---|---|---|---|---|
| | | Alloy | | | | | | | | | oxides having absolute | |
| | | powder of | | SiO₂ | | | Composition of target (mol %) | | | | maximum length larger | Number of |
| Type | | Table 1 | Pt powder | powder | Cr powder | Co powder | Cr | Pt | SiO₂ | Co | than 10 μm | particles |
| Method of | 9A | A: 24.3 | 42.8 | 3.7 | — | Remainder | 18.1 | 18.1 | 5.0 | Remainder | Absent | 66 |
| present | 10A | B: 22.4 | | | | Remainder | | | | Remainder | Absent | 45 |
| invention | 11A | C: 20.8 | | | | Remainder | | | | Remainder | Absent | 57 |
| | 12A | D: 20.0 | | | | Remainder | | | | Remainder | Absent | 48 |
| | 13A | E: 19.3 | | | | Remainder | | | | Remainder | Absent | 58 |
| | 14A | F: 18.4 | | | | Remainder | | | | Remainder | Absent | 55 |
| | 15A | G: 17.8 | | | | Remainder | | | | Remainder | Absent | 75 |
| | 16A | H: 16.9 | | | | Remainder | | | | Remainder | Absent | 92 |
| Compar- | 3A | I: 25.4 | | | | Remainder | | | | Remainder | Present | 150 |
| ative | 4A | J: 16.4 | | | | Remainder | | | | Remainder | Present | 173 |
| method | | | | | | | | | | | | |

| | | | | | | |
|---|---|---|---|---|---|---|
| Conventional | — | 11.4 | Remainder | Remainder | Present | 195 |
| method 2A | | | | | | |

From the results shown in Table 3, it is apparent that the targets produced by the aforementioned methods 9A to 16A of the present invention which were produced by blending the Co—Cr alloy powders A to H having a Cr content of 50 to 70 atomic % and a remainder containing Co as the raw material powders generated less particles as compared to the target produced by the conventional method 2A which was produced by blending and mixing a Co powder having a 50% particle size of 10 μm, a Cr powder having a 50% particle size of 10 μm, a Pt powder having a 50% particle size of 15 μm, and an SiO₂ powder having a 50% particle size of 3 μm without adding a Co—Cr alloy powder. However, it is apparent that the targets produced by the comparative methods 3A and 4A which were produced using the Co—Cr alloy powders I to J having compositions that were outside the scope of the present invention generated numerous particles, and thus were not preferable.

### Example 3

The raw material powders prepared above were blended so as to give the compositions shown in Table 4 and the obtained blended powders were charged in a 10 L container together with a zirconia ball, which will be a grinding medium. The atmosphere inside this container was replaced with an Ar gas atmosphere and thereafter, the container was sealed. This container was rotated for 16 hours using a ball mill to prepare mixed powders.

Methods 17A to 24A of the present invention, comparative methods 5A and 6A, and a conventional method 3A were conducted as follows. The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies having the compositions shown in Table 4. These hot pressed bodies were cut to produce targets having a diameter of 152.4 mm and a thickness of 3 mm

Absolute maximum lengths (maximum value of the distance between the two arbitrary points on the periphery of the particle) of the chromium oxide aggregates dispersed in the microstructure of the targets produced by the aforementioned methods 17A to 24A of the present invention, the comparative methods 5A and 6A, and the conventional method 3A were measured by an EPMA. The presence/absence of coarse chromium oxide aggregates having an absolute maximum length of more than 10 μm is shown in Table 4.

Measurements of the absolute maximum length of chromium oxide aggregates using an EPMA were conducted as follows. Samples were cut out from the targets produced by the aforementioned methods 17A to 24A of the present invention, the comparative methods 5A and 6A, and the conventional method 3A and the sections thereof were embedded in a resin to be subjected to a minor polishing process. Surface analysis was conducted on the structures of these sections using a field emission EPMA (JXA-8500F manufactured by JEOL Ltd.) at an acceleration voltage of 15 kV, an irradiation current of 5×10⁻⁸ A, and a magnification of 1,000 to acquire an element mapping image of Cr. This element mapping image of Cr was made to be an image with a contrast and a color tone so that the regions enriched with Cr (that is, chromium oxide aggregates) can be clearly discriminated as much as possible. The obtained element mapping image of Cr was saved as an image file of bitmap format without degrading the image quality and this image was read separately using image processing software (Win Roof manufactured by Mitani Corporation) to binarize the image. Absolute maximum lengths of the regions enriched with Cr as compared to the matrix were measured by image processing. A threshold value was selected for binarization so that the size of the Cr enriched regions did not change from that of the original image. A scale bar indicated on the original element mapping image of Cr by EPMA was used for the calibration of length during measurements.

Moreover, the targets obtained by the aforementioned methods 17A to 24A of the present invention, the comparative methods 5A and 6A, and the conventional method 3A were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under conditions in which the ultimate vacuum was 5×10⁻⁵ Pa, the electrical power was 800 W in direct current, the Ar gas pressure was 6.0 Pa, the distance between the target and the substrate was 60 mm, and no substrate heating, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 4.

TABLE 4

| | | Composition of raw material powder (% by mass) | | | | | | | | | Presence/absence of Cr | |
|---|---|---|---|---|---|---|---|---|---|---|---|---|
| | | Alloy | | | | | | | | | oxides having absolute | |
| | | powder of | | TiO₂ | | | Composition of target (mol %) | | | | maximum length larger | Number of |
| Type | | Table 1 | Pt powder | powder | Cr powder | Co powder | Cr | Pt | TiO₂ | Co | than 10 μm | particles |
| Method of | 17A | A: 14.6 | 38.4 | 6.8 | — | Remainder | 10.8 | 16.2 | 10.0 | Remainder | Absent | 63 |
| present | 18A | B: 13.4 | | | | Remainder | | | | Remainder | Absent | 48 |
| invention | 19A | C: 12.4 | | | | Remainder | | | | Remainder | Absent | 46 |
| | 20A | D: 12.0 | | | | Remainder | | | | Remainder | Absent | 52 |
| | 21A | E: 11.6 | | | | Remainder | | | | Remainder | Absent | 57 |
| | 22A | F: 11.0 | | | | Remainder | | | | Remainder | Absent | 68 |
| | 23A | G: 10.6 | | | | Remainder | | | | Remainder | Absent | 74 |
| | 24A | H: 10.1 | | | | Remainder | | | | Remainder | Absent | 89 |
| Compar- | 5A | I: 15.2 | | | | Remainder | | | | Remainder | Present | 160 |
| ative | 6A | J: 9.8 | | | | Remainder | | | | Remainder | Present | 168 |
| method | | | | | | | | | | | | |

| | | | | | | |
|---|---|---|---|---|---|---|
| Conventional | — | 6.8 | Remainder | Remainder | Present | 195 |
| method 3A | | | | | | |

Symbols (*) indicate conditions outside the scope of the present invention.

From the results shown in Table 4, it is apparent that the targets produced by the aforementioned methods 17A to 24A of the present invention which were produced by blending the Co—Cr alloy powders A to H having a Cr content of 50 to 70 atomic % and a remainder containing Co as the raw material powders generated less particles as compared to the target produced by the conventional method 3A which was produced by blending and mixing a Co powder having a 50% particle size of 10 μm, a Cr powder having a 50% particle size of 10 μm, a Pt powder having a 50% particle size of 15 μm, and an TiO₂ powder having a 50% particle size of 3 μm without adding a Co—Cr alloy powder. However, it is apparent that the targets produced by the comparative methods 5A and 6A which were produced using the Co—Cr alloy powders I to J having compositions that were outside the scope of the present invention generated numerous particles, and thus were not preferable.

### Example 4

The raw material powders prepared above were blended so as to give the compositions shown in Table 5 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

The obtained mixed powders were filled in an SUS container and were subjected to a vacuum degassing treatment under conditions in which the powders were retained at a temperature of 550° C. for 12 hours, and thereafter the mixed powders were vacuum encapsulated by sealing the SUS container. Methods 25A to 32A of the present invention, comparative methods 7A and 8A, and a conventional method 4A were conducted as follows. The SUS container filled with the mixed powders was subjected to a hot isostatic pressing process under conditions in which the powders were retained at a temperature of 1,200° C. and a pressure of 100 MPa for 3 hours followed by opening the SUS container to produce hot isostatic pressed bodies having the compositions shown in Table 5. These hot isostatic pressed bodies were cut to produce targets having a diameter of 152.4 mm and a thickness of 3 mm

Absolute maximum lengths (maximum value of the distance between the two arbitrary points on the periphery of the particle) of the chromium oxide aggregates dispersed in the microstructure of the targets produced by the aforementioned methods 25A to 32A of the present invention, the comparative methods 7A and 8A, and the conventional method 4A were measured by an EPMA. The presence/absence of coarse chromium oxide aggregates having an absolute maximum length of more than 10 μm is shown in Table 5.

Measurements of the absolute maximum length of chromium oxide aggregates using an EPMA were conducted as follows. Samples were cut out from the targets produced by the aforementioned methods 25A to 32A of the present invention, the comparative methods 7A and 8A, and the conventional method 4A and the sections thereof were embedded in a resin to be subjected to a minor polishing process. Surface analysis was conducted on the structures of these sections using a field emission EPMA (JXA-8500F manufactured by JEOL Ltd.) at an acceleration voltage of 15 kV, an irradiation current of 5×10⁻⁸ A, and a magnification of 1,000 to acquire an element mapping image of Cr. This element mapping image of Cr was made to be an image with a contrast and a color tone so that the regions enriched with Cr (that is, chromium oxide aggregates) can be clearly discriminated as much as possible. The obtained element mapping image of Cr was saved as an image file of bitmap format without degrading the image quality and this image was read separately using image processing software (Win Roof manufactured by Mitani Corporation) to binarize the image. Absolute maximum lengths of the regions enriched with Cr as compared to the matrix were measured by image processing. A threshold value was selected for binarization so that the size of the Cr enriched regions did not change from that of the original image. A scale bar indicated on the original element mapping image of Cr by EPMA was used for the calibration of length during measurements.

Moreover, the targets obtained by the aforementioned methods 25A to 32A of the present invention, the comparative methods 7A and 8A, and the conventional method 4A were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under conditions in which the ultimate vacuum was 5×10⁻⁵ Pa, the electrical power was 800 W in direct current, the Ar gas pressure was 6.0 Pa, the distance between the target and the substrate was 60 mm, and no substrate heating, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 5.

TABLE 5

| | | Composition of raw material powder (% by mass) | | | | | | | | | Presence/absence of Cr | |
|---|---|---|---|---|---|---|---|---|---|---|---|---|
| | | Alloy | | | | | | | | | oxides having absolute | |
| | | powder of | | Ta₂O₅ | | Co | Composition of target (mol %) | | | | maximum length larger | Number of |
| Type | | Table 1 | Pt powder | powder | Cr powder | powder | Cr | Pt | Ta₂O₅ | Co | than 10 μm | particles |
| Method of | 25A | A: 19.8 | 34.8 | 21.8 | — | Remainder | 18.1 | 18.1 | 5.0 | Remainder | Absent | 65 |
| present | 26A | B: 18.2 | | | | Remainder | | | | Remainder | Absent | 52 |
| invention | 27A | C: 16.9 | | | | Remainder | | | | Remainder | Absent | 54 |
| | 28A | D: 16.3 | | | | Remainder | | | | Remainder | Absent | 55 |
| | 29A | E: 15.7 | | | | Remainder | | | | Remainder | Absent | 62 |
| | 30A | F: 14.9 | | | | Remainder | | | | Remainder | Absent | 68 |
| | 31A | G: 14.5 | | | | Remainder | | | | Remainder | Absent | 75 |
| | 32A | H: 13.8 | | | | Remainder | | | | Remainder | Absent | 86 |
| Compar- | 7A | I: 20.7 | | | | Remainder | | | | Remainder | Present | 125 |
| ative | 8A | J: 13.4 | | | | Remainder | | | | Remainder | Present | 147 |
| method | | | | | | | | | | | | |

| | | | | | | |
|---|---|---|---|---|---|---|
| Conventional | — | 9.3 | Remainder | Remainder | Present | 155 |
| method 4A | | | | | | |

From the results shown in Table 5, it is apparent that the targets produced by the aforementioned methods 25A to 32A of the present invention which were produced by blending the Co—Cr alloy powders A to H having a Cr content of 50 to 70 atomic % and a remainder containing Co as the raw material powders generated less particles as compared to the target produced by the conventional method 4A which was produced by blending and mixing a Co powder having a 50% particle size of 10 μm, a Cr powder having a 50% particle size of 10 μm, a Pt powder having a 50% particle size of 15 μm, and an Ta₂O₅ powder having a 50% particle size of 3 μm without adding a Co—Cr alloy powder. However, it is apparent that the targets produced by the comparative methods 7A and 8A which were produced using the Co—Cr alloy powders I to J having compositions that were outside the scope of the present invention generated numerous particles, and thus were not preferable.

### <Second Aspect>

Cr—Pt binary alloy powders A to S having chemical compositions shown in Table 6 were prepared as raw material powders by a gas atomizing method. Since the Cr—Pt binary alloy powders A to S obtained by the gas atomizing method had a 50% particle size of 95 μm, the Cr—Pt binary alloy powders A to S were classified using a sieve with an aperture size of 45 μm so that the 50% particle size of all the powders measured by a laser diffraction method would be 35 μm.

In addition, Co—Cr binary alloy powders a to j having chemical compositions shown in Table 7 were prepared as raw material powders by a gas atomizing method. Since the Co—Cr binary alloy powders a to j obtained by the gas atomizing method had a 50% particle size of 95 μm, the Co—Cr binary alloy powders a to j were classified using a sieve with an aperture size of 45 μm so that the 50% particle size of all the powders measured by a laser diffraction method would be 35 μm. Moreover, a Co powder having a 50% particle size of 10 μm, a Pt powder having a 50% particle size of 15 μm, an SiO₂ powder having a 50% particle size of 3 μm, a TiO₂ powder having a 50% particle size of 3 μm, a Ta₂O₅ powder having a 50% particle size of 3 μm, and a Cr powder having a 50% particle size of 10 μm which were commercially available were prepared.

TABLE 6

| | | | Composition | |
|---|---|---|---|---|
| | | 50% particle | (atomic %) | |
| Type | | size (μm) | Pt | Cr |
| Cr—Pt | A | 35 | 10 | Remainder |
| binary | B | | 15 | Remainder |
| alloy | C | | 20 | Remainder |
| powder | D | | 25 | Remainder |
| | E | | 30 | Remainder |
| | F | | 35 | Remainder |
| | G | | 40 | Remainder |
| | H | | 45 | Remainder |
| | I | | 50 | Remainder |
| | J | | 55 | Remainder |
| | K | | 60 | Remainder |
| | L | | 65 | Remainder |
| | M | | 70 | Remainder |
| | N | | 75 | Remainder |
| | O | | 80 | Remainder |
| | P | | 85 | Remainder |
| | Q | | 90 | Remainder |
| | R | | 5* | Remainder |
| | S | | 95* | Remainder |

Symbols (*) indicate conditions outside the scope of the present invention.

TABLE 7

| | | | Composition | |
|---|---|---|---|---|
| | | 50% particle | (atomic %) | |
| Type | | size (μm) | Cr | Co |
| Co—Cr | a | 35 | 50 | Remainder |
| binary | b | | 54 | Remainder |
| alloy | c | | 58 | Remainder |
| powder | d | | 60 | Remainder |
| | e | | 62 | Remainder |
| | f | | 65 | Remainder |
| | g | | 67 | Remainder |
| | h | | 70 | Remainder |
| | i | | 48* | Remainder |
| | j | | 72* | Remainder |

Symbols (*) indicate conditions outside the scope of the present invention.

### Example 5

The raw material powders prepared above were blended so as to give the compositions shown in Table 8 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

Methods 1B to 11B of the present invention, a comparative method 1B, and a conventional method 1B were conducted as follows. The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies. These hot pressed bodies were cut to produce targets having a diameter of 152.4 mm and a thickness of 3 mm as well as a chemical composition consisting of 10.1 mol % of Cr, 15.6 mol % of Pt, 8.0 mol % of SiO₂ and a remainder containing Co.

Absolute maximum lengths (maximum value of the distance between the two arbitrary points on the periphery of the particle) of the chromium oxide aggregates dispersed in the microstructure of the targets produced by the aforementioned methods 1B to 11B of the present invention, the comparative method 1B, and the conventional method 1B were measured by an EPMA. The presence/absence of coarse chromium oxide aggregates having an absolute maximum length of more than 10 μm is shown in Table 8.

Measurements of the absolute maximum length of chromium oxide aggregates using an EPMA were conducted as follows. Samples were cut out from the hot pressed bodies produced by the aforementioned methods 1B to 11B of the present invention, the comparative method 1B, and the conventional method 1B and the sections thereof were embedded in a resin to be subjected to a minor polishing process. Surface analysis was conducted on the structures of these sections using a field emission EPMA (JXA-8500F manufactured by JEOL Ltd.) at an acceleration voltage of 15 kV, an irradiation current of 5×10⁻⁸ A, and a magnification of 1,000 to acquire an element mapping image of Cr. This element mapping image of Cr was made to be an image with a contrast and a color tone so that the regions enriched with Cr (that is, chromium oxide aggregates) could be clearly discriminated as much as possible. The obtained element mapping image of Cr was saved as an image file of bitmap format without degrading the image quality and this image was read separately using image processing software (Win Roof manufactured by Mitani Corporation) to binarize the image. Absolute maximum lengths of the regions enriched with Cr as compared to the matrix were measured by image processing. A threshold value was selected for binarization so that the size of the Cr enriched regions did not change from that of the original image. A scale bar indicated on the original element mapping image of Cr by EPMA was used for the calibration of length during measurements.

Moreover, the targets obtained by the aforementioned methods 1B to 11B of the present invention, the comparative method 1B, and the conventional method 1B were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under conditions in which the ultimate vacuum was 5×10⁻⁵ Pa, the electrical power was 800 W in direct current, the Ar gas pressure was 6.0 Pa, the distance between the target and the substrate was 60 mm, and no substrate heating, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 8.

TABLE 8

| | | Composition of raw material powder (% by mass) | | | | | | |
|---|---|---|---|---|---|---|---|---|
| | | Pt—Cr | | | | | | |
| | | binary | | | | | Presence/absence of Cr | Number of |
| | | alloy | | | | | oxides having absolute | particles of |
| | | powder of | | SiO₂ | | | maximum length larger | 1.0 μm or |
| Type | | Table 6 | Pt powder | powder | Cr powder | Co powder | than 10 μm | larger |
| Method of | 1B | A: 9.4 | 35.6 | 6.04 | — | Remainder | Absent | 65 |
| present | 2B | B: 11.0 | 33.9 | | | Remainder | Absent | 43 |
| invention | 3B | C: 12.8 | 32.1 | | | Remainder | Absent | 35 |
| | 4B | D: 14.9 | 30.1 | | | Remainder | Absent | 37 |
| | 5B | E: 17.2 | 27.7 | | | Remainder | Absent | 45 |
| | 6B | F: 20.0 | 25.0 | | | Remainder | Absent | 48 |
| | 7B | G: 23.1 | 21.8 | | | Remainder | Absent | 46 |
| | 8B | H: 26.9 | 18.0 | | | Remainder | Absent | 51 |
| | 9B | I: 31.4 | 13.5 | | | Remainder | Absent | 49 |
| | 10B | J: 36.9 | 8.0 | | | Remainder | Absent | 54 |
| | 11B | K: 43.8 | 1.1 | | | Remainder | Absent | 56 |

| | | | | | | |
|---|---|---|---|---|---|---|
| Comparative method 1B | R: 7.9 | 37.0 | | Remainder | Present | 101 |
| Conventional method 1B | — | 38.3 | 6.6 | Remainder | Present | 205 |

Pressure sintering process: vacuum hot pressing method

From the results shown in Table 8, it is apparent that the targets produced by the aforementioned methods 1B to 11B of the present invention which were produced by blending the Cr—Pt binary alloy powders A to K having a Pt content of 10 to 90 atomic % and a remainder containing Cr as the raw material powders generated less particles as compared to the target produced by the conventional method 1B which was produced by blending and mixing a Co powder having a 50% particle size of 10 μm, a Cr powder having a 50% particle size of 10 μm, a Pt powder having a 50% particle size of 15 μm, and an SiO₂ powder having a 50% particle size of 3 μm without adding a Cr—Pt binary alloy powder. However, it is apparent that the target produced by the comparative method 1B which was produced using the Cr—Pt binary alloy powder R having a composition that was outside the scope of the present invention generated numerous particles, and thus was not preferable.

### Example 6

The Cr—Pt binary alloy powders A to G shown in Table 6, the Co powder, the Pt powder, and the SiO₂ powder were blended so as to give the compositions shown in Table 9 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders. The mixed powders obtained as described above were filled in an SUS container and were subjected to a vacuum degassing treatment under conditions in which the powders were retained at a temperature of 550° C. for 12 hours, and thereafter the mixed powders were vacuum encapsulated by sealing the SUS container. Methods 12B to 18B of the present invention, a comparative method 2B, and a conventional method 2B were conducted as follows. The SUS container filled with the mixed powders was subjected to a hot isostatic pressing process under conditions in which the powders were retained at a temperature of 1,200° C. and a pressure of 100 MPa for 3 hours followed by opening the SUS container to produce hot isostatic pressed bodies having a chemical composition formed of 17.1 mol % of Cr, 15.3 mol % of Pt, 10.0 mol % of SiO₂ and a remainder containing Co. These hot isostatic pressed bodies were cut to produce targets having a diameter of 152.4 mm and a thickness of 3 mm. The same measurements as those in Example 5 were conducted on the targets obtained by the aforementioned methods 12B to 18B of the present invention, the comparative method 2B, and the conventional method 2B. The results are shown in Table 9.

TABLE 9

| | | Composition of raw material powder (% by mass) | | | | | | |
|---|---|---|---|---|---|---|---|---|
| | | Pt—Cr | | | | | | |
| | | binary | | | | | Presence/absence of Cr | Number of |
| | | alloy | | | | | oxides having absolute | particles of |
| | | powder of | | SiO₂ | | | maximum length larger | 1.0 μm or |
| Type | | Table 6 | Pt powder | powder | Cr powder | Co powder | than 10 μm | larger |
| Method of | 12B | A: 16.0 | 33.2 | 7.6 | — | Remainder | Absent | 67 |
| present | 13B | B: 18.8 | 30.4 | | | Remainder | Absent | 52 |
| invention | 14B | C: 21.9 | 27.3 | | | Remainder | Absent | 39 |
| | 15B | D: 25.4 | 23.8 | | | Remainder | Absent | 38 |
| | 16B | E: 29.5 | 19.8 | | | Remainder | Absent | 45 |
| | 17B | F: 34.1 | 15.1 | | | Remainder | Absent | 46 |
| | 18B | G: 39.6 | 9.7 | | | Remainder | Absent | 44 |

| | | | | | | |
|---|---|---|---|---|---|---|
| Comparative method 2B | R: 13.5 | 35.7 | | Remainder | Present | 112 |
| Conventional method 2B | — | 37.9 | 11.3 | Remainder | Present | 193 |

Pressure sintering process: hot isostatic pressing method

From the results shown in Table 9, it is apparent that the targets produced by the aforementioned methods 12B to 18B of the present invention which were produced by blending the Cr—Pt binary alloy powders A to G having a Pt content of 10 to 90 atomic % and a remainder containing Cr as the raw material powders generated less particles as compared to the target produced by the conventional method 2B which was produced by blending and mixing a Co powder having a 50% particle size of 10 μm, a Cr powder having a 50% particle size of 10 μm, a Pt powder having a 50% particle size of 15 μm, and an SiO₂ powder having a 50% particle size of 3 μm without adding a Cr—Pt binary alloy powder. However, it is apparent that the target produced by the comparative method 2B which was produced using the Cr—Pt alloy powder R having a composition that was outside the scope of the present invention generated numerous particles, and thus was not preferable.

### Example 7

The Cr—Pt binary alloy powders A to J shown in Table 6, the Co—Cr binary alloy powders a to h shown in Table 7, the Co powder, the Pt powder, and the SiO₂ powder were blended so as to give the compositions shown in Table 10 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

Methods 19B to 28B of the present invention, a comparative method 3B, and a conventional method 3B were conducted as follows. The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies having a chemical composition formed of 11.3 mol % of Cr, 12.2 mol % of Pt, 6.0 mol % of SiO₂ and a remainder containing Co. These hot pressed bodies were cut to produce targets having a diameter of 152.4 mm and a thickness of 3 mm

Absolute maximum lengths (maximum value of the distance between the two arbitrary points on the periphery of the particle) of the chromium oxide aggregates dispersed in the microstructure of the targets produced by the aforementioned methods 19B to 28B of the present invention, the comparative method 3B, and the conventional method 3B were measured by an EPMA. The presence/absence of coarse chromium oxide aggregates having an absolute maximum length of more than 10 μm is shown in Table 10.

Measurements of the absolute maximum length of chromium oxide aggregates using an EPMA were conducted by cutting out samples from the targets produced by the aforementioned methods 19B to 28B of the present invention, the comparative method 3B, and the conventional method 3B, and embedding the sections thereof in a resin to be subjected to a mirror polishing process, and the rest of the procedures were carried out as in Example 5.

Moreover, the targets obtained by the aforementioned methods 19B to 28B of the present invention, the comparative method 3B, and the conventional method 3B were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under the same conditions as those in Example 5 to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 10.

TABLE 10

| | | Composition of raw material powder (% by mass) | | | | | | | |
|---|---|---|---|---|---|---|---|---|---|
| | | Cr—Pt | Co—Cr | | | | | Presence/absence | |
| | | binary | binary | | | | | of Cr oxides | Number of |
| | | alloy | alloy | | | | | having absolute | particles of |
| | | powder of | powder of | | SiO₂ | | | maximum length | 1.0 μm or |
| Type | | Table 6 | Table 7 | Pt powder | powder | Cr powder | Co powder | larger than 10 μm | larger |
| Method of | 19B | A: 5.6 | d: 6.9 | 30.2 | 4.82 | — | Remainder | Absent | 60 |
| present | 20B | B: 6.5 | h: 5.8 | 29.3 | | | Remainder | Absent | 38 |
| invention | 21B | C: 7.6 | a: 8.4 | 28.2 | | | Remainder | Absent | 22 |
| | 22B | D: 8.8 | e: 6.6 | 26.9 | | | Remainder | Absent | 31 |
| | 23B | E: 10.2 | g: 6.1 | 25.5 | | | Remainder | Absent | 47 |
| | 24B | F: 11.8 | b: 7.7 | 23.9 | | | Remainder | Absent | 45 |
| | 25B | G: 13.7 | c: 7.1 | 22.0 | | | Remainder | Absent | 42 |
| | 26B | H: 15.9 | f: 6.3 | 19.8 | | | Remainder | Absent | 53 |
| | 27B | I: 18.6 | b: 7.7 | 17.1 | | | Remainder | Absent | 50 |
| | 28B | J: 21.9 | g: 6.1 | 13.9 | | | Remainder | Absent | 74 |

| | | | | | | | |
|---|---|---|---|---|---|---|---|
| Comparative method 3B | R: 4.7 | i: 8.7 | 31.1 | | Remainder | Present | 125 |
| Conventional method 3B | — | — | 31.9 | 7.8 | Remainder | Present | 201 |

Pressure sintering process: vacuum hot pressing method

From the results shown in Table 10, it is apparent that the targets produced by the aforementioned methods 19B to 28B of the present invention which were produced by blending the Cr—Pt binary alloy powders shown in Table 6 and the Co—Cr binary alloy powders shown in Table 7 as the raw material powders generated less particles as compared to the target produced by the conventional method 3B shown in Table 10 which was produced by blending and mixing a Co powder having a 50% particle size of 10 μm, a Cr powder having a 50% particle size of 10 μm, a Pt powder having a 50% particle size of 15 μm, and an SiO₂ powder having a 50% particle size of 3 μm without adding a Cr—Pt binary alloy powder and a Co—Cr binary alloy powder. However, it is apparent that the target produced by the comparative method 3B which was produced using the Co—Cr alloy powder i having a composition that was outside the scope of the present invention shown in Table 7 generated numerous particles which were 1.0 μm or larger, and thus was not preferable.

### Example 8

Methods 29B to 35B of the present invention, a comparative method 4B, and a conventional method 4B were conducted under the same conditions as those in Example 7 except that no Pt powder was used and all the necessary Pt components were included by adding the Cr—Pt binary alloy powders K to Q shown in Table 6 and that a pressure sintering process was conducted by the same hot isostatic pressing process as in Example 6. The hot isostatic pressed bodies having a chemical composition consisting of 11.8 mol % of Cr, 15.5 mol % of Pt, 9.0 mol % of SiO₂ and a remainder containing Co were produced and these hot isostatic pressed bodies were cut to produce targets having a diameter of 152.4 mm and a thickness of 3 mm. The same measurements as those in Example 5 were conducted on the targets obtained by the aforementioned methods 29B to 35B of the present invention, the comparative method 4B, and the conventional method 4B. The results are shown in Table 11.

TABLE 11

| | | Composition of raw material powder (% by mass) | | | | | | | |
|---|---|---|---|---|---|---|---|---|---|
| | | Pt—Cr | Co—Cr | | | | | Presence/absence | |
| | | binary | binary | | | | | of Cr oxides | Number of |
| | | alloy | alloy | | | | | having absolute | particles of |
| | | powder of | powder of | | SiO₂ | | | maximum length | 1.0 μm or |
| Type | | Table 6 | Table 7 | Pt powder | powder | Cr powder | Co powder | larger than 10 μm | larger |
| Method of | 29B | K: 44.8 | h: 1.5 | — | 6.8 | — | Remainder | Absent | 71 |
| present | 30B | L: 43.5 | g: 3.6 | | | | Remainder | Absent | 51 |
| invention | 31B | M: 42.4 | e: 5.5 | | | | Remainder | Absent | 45 |
| | 32B | N: 41.4 | c: 8.0 | | | | Remainder | Absent | 48 |
| | 33B | O: 40.6 | a: 11.1 | | | | Remainder | Absent | 60 |
| | 34B | P: 39.9 | f: 9.6 | | | | Remainder | Absent | 64 |
| | 35B | Q: 39.2 | d: 11.6 | | | | Remainder | Absent | 69 |

| | | | | | | | |
|---|---|---|---|---|---|---|---|
| Comparative | S: 38.6 | j: 10.4 | | | Remainder | Present | 125 |
| method 4B | | | | | | | |
| Conventional | — | — | 38.1 | 7.8 | Remainder | Present | 194 |
| method 4B | | | | | | | |

Pressure sintering process: hot isostatic pressing method

From the results shown in Table 11, it is apparent that the targets produced by the aforementioned methods 29B to 35B of the present invention generated less particles as compared to the target produced by the conventional method 4B which was produced by blending and mixing a Co powder having a 50% particle size of 10 μm, a Cr powder having a 50% particle size of 10 μm, a Pt powder having a 50% particle size of 15 μm, and an SiO₂ powder having a 50% particle size of 3 μm without adding a Cr—Pt binary alloy powder and a Co—Cr binary alloy powder. However, it is apparent that the target produced by the comparative method 4B which was produced using the Cr—Pt binary alloy powder S shown in Table 6 having a composition that was outside the scope of the present invention and the Co—Cr binary alloy powder j shown in Table 7 having a composition that was outside the scope of the present invention generated numerous particles, and thus was not preferable.

### Example 9

The raw material powders were blended so as to give the compositions shown in Table 12 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders. Methods 36B to 44B of the present invention, a comparative method 5B, and a conventional method 5B were conducted as follows. The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies. These hot pressed bodies were cut to produce targets having a diameter of 152.4 mm and a thickness of 3 mm as well as a composition consisting of 14.7 mol % of Cr, 16.6 mol % of Pt, 8.0 mol % of TiO₂ and a remainder containing Co.

Absolute maximum lengths (maximum value of the distance between the two arbitrary points on the periphery of the particle) of the chromium oxide aggregates dispersed in the microstructure of the targets produced by the aforementioned methods 36B to 44B of the present invention, the comparative method 5B, and the conventional method 5B were measured by an EPMA in the same manner as in Example 5. The presence/absence of coarse chromium oxide aggregates having an absolute maximum length of more than 10 μm is shown in Table 12.

Moreover, the targets obtained by the aforementioned methods 36B to 44B of the present invention, the comparative method 5B, and the conventional method 5B were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under the same conditions as those in Example 5. Subsequently, the number of particles attached on the wafer surface and having a size of 1.0 μm or more was counted in the same manner as in Example 5 and the average value of the counts obtained from 25 wafers was calculated. The results are shown in Table 12.

TABLE 12

| | | Composition of raw material powder (% by mass) | | | | | | |
|---|---|---|---|---|---|---|---|---|
| | | Pt—Cr | | | | | Presence/absence | |
| | | binary | | | | | of Cr oxides | Number of |
| | | alloy | | | | | having absolute | particles of |
| | | powder of | | TiO₂ | | | maximum length | 1.0 μm or |
| Type | | Table 6 | Pt powder | powder | Cr powder | Co powder | larger than 10 μm | larger |
| Method of | 36B | A: 13.2 | 35.4 | 7.8 | — | Remainder | Absent | 60 |
| present | 37B | B: 15.5 | 33.2 | | | Remainder | Absent | 45 |
| invention | 38B | C: 18.1 | 30.6 | | | Remainder | Absent | 32 |
| | 39B | D: 21.0 | 27.7 | | | Remainder | Absent | 35 |
| | 40B | E: 24.3 | 24.3 | | | Remainder | Absent | 39 |
| | 41B | F: 28.1 | 20.5 | | | Remainder | Absent | 46 |
| | 42B | G: 32.6 | 16.0 | | | Remainder | Absent | 48 |
| | 43B | H: 37.9 | 10.7 | | | Remainder | Absent | 51 |
| | 44B | I: 44.3 | 4.4 | | | Remainder | Absent | 55 |

| | | | | | | |
|---|---|---|---|---|---|---|
| Comparative | R: 11.2 | 37.5 | | Remainder | Present | 107 |
| method 5B | | | | | | |
| Conventional | — | 39.3 | 9.3 | Remainder | Present | 189 |
| method 5B | | | | | | |

Pressure sintering process: vacuum hot pressing method

From the results shown in Table 12, it is apparent that the targets produced by the aforementioned methods 36B to 44B of the present invention which were produced by blending the Cr—Pt binary alloy powders A to K having a Pt content of 10 to 90 atomic % and a remainder containing Cr as the raw material powders generated less particles as compared to the target produced by the conventional method 5B which was produced by blending and mixing a Co powder having a 50% particle size of 10 μm, a Cr powder having a 50% particle size of 10 μm, a Pt powder having a 50% particle size of 15 μm, and an TiO₂ powder having a 50% particle size of 3 μm without adding a Cr—Pt binary alloy powder. However, it is apparent that the target produced by the comparative method 5B which was produced using the Cr—Pt binary alloy powder R having a composition that was outside the scope of the present invention generated numerous particles, and thus was not preferable.

### Example 10

The Cr—Pt binary alloy powders A to G shown in Table 6, the Co powder, the Pt powder, and the TiO₂ powder were blended so as to give the compositions shown in Table 13 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders. The mixed powders obtained as described above were filled in an SUS container and were subjected to a vacuum degassing treatment under conditions in which the powders were retained at a temperature of 550° C. for 12 hours, and thereafter the mixed powders were vacuum encapsulated by sealing the SUS container. Methods 45B to 53B of the present invention, a comparative method 6B, and a conventional method 6B were conducted as follows. The SUS container filled with the mixed powders was subjected to a hot isostatic pressing process under conditions in which the powders were retained at a temperature of 1,200° C. and a pressure of 100 MPa for 3 hours followed by opening the SUS container to produce hot isostatic pressed bodies having a chemical composition consisting of 13.5 mol % of Cr, 14.4 mol % of Pt, 10.0 mol % of TiO₂ and a remainder containing Co. These hot isostatic pressed bodies were cut to produce targets having a diameter of 152.4 mm and a thickness of 3 mm. The same measurements as those in Example 5 were conducted on the targets obtained by the aforementioned methods 45B to 53B of the present invention, the comparative method 6B, and the conventional method 6B. The results are shown in Table 13.

TABLE 13

| | | Composition of raw material powder (% by mass) | | | | | | |
|---|---|---|---|---|---|---|---|---|
| | | Pt—Cr | | | | | Presence/absence | |
| | | binary | | | | | of Cr oxides | Number of |
| | | alloy | | | | | having absolute | particles of |
| | | powder of | | TiO₂ | | | maximum length | 1.0 μm or |
| Type | | Table 6 | Pt powder | powder | Cr powder | Co powder | larger than 10 μm | larger |
| Method of | 45B | A: 12.5 | 31.6 | 10.0 | — | Remainder | Absent | 62 |
| present | 46B | B: 14.6 | 29.4 | | | Remainder | Absent | 48 |
| invention | 47B | C: 17.1 | 27.0 | | | Remainder | Absent | 42 |
| | 48B | D: 19.8 | 24.2 | | | Remainder | Absent | 36 |
| | 49B | E: 23.0 | 21.1 | | | Remainder | Absent | 37 |
| | 50B | F: 26.6 | 17.5 | | | Remainder | Absent | 43 |
| | 51B | G: 30.8 | 13.2 | | | Remainder | Absent | 48 |
| | 52B | H: 35.8 | 8.2 | | | Remainder | Absent | 52 |
| | 53B | I: 41.9 | 2.2 | | | Remainder | Absent | 51 |

| | | | | | | |
|---|---|---|---|---|---|---|
| Comparative | R: 10.5 | 33.5 | | Remainder | Present | 108 |
| method 6B | | | | | | |
| Conventional | — | 35.3 | 8.8 | Remainder | Present | 183 |
| method 6B | | | | | | |

Pressure sintering process: hot isostatic pressing method

From the results shown in Table 13, it is apparent that the targets produced by the aforementioned methods 45B to 53B of the present invention which were produced by blending the Cr—Pt binary alloy powders A to G having a Pt content of 10 to 90 atomic % and a remainder containing Cr as the raw material powders generated less particles as compared to the target produced by the conventional method 6B which was produced by blending and mixing a Co powder having a 50% particle size of 10 μm, a Cr powder having a 50% particle size of 10 μm, a Pt powder having a 50% particle size of 15 μm, and an TiO₂ powder having a 50% particle size of 3 μm without adding a Cr—Pt binary alloy powder. However, it is apparent that the target produced by the comparative method 6B which was produced using the Cr—Pt alloy powder R having a composition that was outside the scope of the present invention generated numerous particles, and thus was not preferable.

### Example 11

The Cr—Pt binary alloy powders A to J shown in Table 6, the Co—Cr binary alloy powders a to h shown in Table 7, the Co powder, the Pt powder, and the TiO₂ powder were blended so as to give the compositions shown in Table 14 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

Methods 54B to 63B of the present invention, a comparative method 7B, and a conventional method 7B were conducted as follows. The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies having a chemical composition formed of 13.2 mol % of Cr, 12.2 mol % of Pt, 6.0 mol % of TiO₂ and a remainder containing Co. These hot pressed bodies were cut to produce targets having a diameter of 152.4 mm and a thickness of 3 mm

Absolute maximum lengths (maximum value of the distance between the two arbitrary points on the periphery of the particle) of the chromium oxide aggregates dispersed in the microstructure of the targets produced by the aforementioned methods 54B to 63B of the present invention, the comparative method 7B, and the conventional method 7B were measured by an EPMA. The presence/absence of coarse chromium oxide aggregates having an absolute maximum length of more than 10 μm is shown in Table 14.

Measurements of the absolute maximum length of chromium oxide aggregates using an EPMA were conducted by cutting out samples from the targets produced by the aforementioned methods 54B to 63B of the present invention, the comparative method 7B, and the conventional method 7B, and embedding the sections thereof in a resin to be subjected to a minor polishing process, and the rest of the procedures were carried out in the same manner as in Example 5.

Moreover, the targets obtained by the aforementioned methods 54B to 63B of the present invention, the comparative method 7B, and the conventional method 7B were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under the same conditions as those in Example 5 to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 14.

TABLE 14

| | | Composition of raw material powder (% by mass) | | | | | | | |
|---|---|---|---|---|---|---|---|---|---|
| | | Cr—Pt | Co—Cr | | | | | Presence/absence | |
| | | binary | binary | | | | | of Cr oxides | Number of |
| | | alloy | alloy | | | | | having absolute | particles of |
| | | powder of | powder of | | TiO₂ | | | maximum length | 1.0 μm or |
| Type | | Table 6 | Table 7 | Pt powder | powder | Cr powder | Co powder | larger than 10 μm | larger |
| Method of | 54B | A: 6.4 | d: 7.9 | 29.5 | 6.3 | — | Remainder | Absent | 58 |
| present | 55B | B: 7.5 | h: 6.7 | 28.4 | | | Remainder | Absent | 45 |
| invention | 56B | C: 8.7 | a: 9.6 | 27.2 | | | Remainder | Absent | 34 |
| | 57B | D: 10.1 | e: 7.6 | 25.8 | | | Remainder | Absent | 29 |
| | 58B | E: 11.8 | g: 7.0 | 24.2 | | | Remainder | Absent | 33 |
| | 59B | F: 13.6 | b: 8.9 | 22.3 | | | Remainder | Absent | 39 |
| | 60B | G: 15.8 | c: 8.2 | 20.1 | | | Remainder | Absent | 44 |
| | 61B | H: 18.3 | f: 7.3 | 17.6 | | | Remainder | Absent | 45 |
| | 62B | I: 21.4 | b: 8.9 | 14.5 | | | Remainder | Absent | 51 |
| | 63B | J: 25.2 | g: 7.0 | 10.7 | | | Remainder | Absent | 62 |

| | | | | | | | |
|---|---|---|---|---|---|---|---|
| Comparative | R: 5.4 | i: 10.0 | 30.5 | | Remainder | Present | 112 |
| method 7B | | | | | | | |
| Conventional | — | — | 31.4 | 9.0 | Remainder | Present | 190 |
| method 7B | | | | | | | |

Pressure sintering process: vacuum hot pressing method

From the results shown in Table 14, it is apparent that the targets produced by the aforementioned methods MB to 63B of the present invention which were produced by blending the Cr—Pt binary alloy powders shown in Table 6 and the Co—Cr binary alloy powders shown in Table 7 as the raw material powders generated less particles as compared to the target produced by the conventional method 7B which was produced by blending and mixing a Co powder having a 50% particle size of 10 μm, a Cr powder having a 50% particle size of 10 μm, a Pt powder having a 50% particle size of 15 μm, and an TiO₂ powder having a 50% particle size of 3 μm without adding the Cr—Pt binary alloy powder and Co—Cr binary alloy powder shown in Table 14. However, it is apparent that the target produced by the comparative method 7B which was produced using the Co—Cr alloy powder i having a composition that was outside the scope of the present invention shown in Table 7 generated numerous particles which were 1.0 μm or larger, and thus was not preferable.

### Example 12

Methods 64B to 70B of the present invention, a comparative method 8B, and a conventional method 8B were conducted with exactly the same conditions as those in Example 7 except that no Pt powder was used and all the necessary Pt components were included by adding the Cr—Pt binary alloy powders K to Q shown in Table 6, a TiO₂ powder was used as a non-magnetic oxide powder, and that a pressure sintering process was conducted by the same hot isostatic pressing process as in Example 6. The hot isostatic pressed bodies having a chemical composition consisting of 9.1 mol % of Cr, 10.9 mol % of Pt, 9.0 mol % of TiO₂ and a remainder containing Co were produced and these hot isostatic pressed bodies were cut to produce targets having a diameter of 152.4 mm and a thickness of 3 mm. The same measurements as those in Example 5 were conducted on the targets obtained by the aforementioned methods 64B to 70B of the present invention, the comparative method 8B, and the conventional method 8B. The results are shown in Table 15.

TABLE 15

| | | Composition of raw material powder (% by mass) | | | | | | | |
|---|---|---|---|---|---|---|---|---|---|
| | | Pt—Cr | Co—Cr | | | | | Presence/absence | |
| | | binary | binary | | | | | of Cr oxides | Number of |
| | | alloy | alloy | | | | | having absolute | particles of |
| | | powder of | powder of | | TiO₂ | | | maximum length | 1.0 μm or |
| Type | | Table 6 | Table 7 | Pt powder | powder | Cr powder | Co powder | larger than 10 μm | larger |
| Method of | 64B | K: 33.4 | h: 1.9 | — | 9.6 | — | Remainder | Absent | 69 |
| present | 65B | L: 32.5 | g: 3.5 | | | | Remainder | Absent | 55 |
| invention | 66B | M: 31.6 | e: 4.9 | | | | Remainder | Absent | 49 |
| | 67B | N: 30.9 | c: 6.9 | | | | Remainder | Absent | 42 |
| | 68B | O: 30.3 | a: 9.4 | | | | Remainder | Absent | 50 |
| | 69B | P: 29.7 | f: 8.0 | | | | Remainder | Absent | 53 |
| | 70B | Q: 29.2 | d: 9.6 | | | | Remainder | Absent | 61 |

| | | | | | | | |
|---|---|---|---|---|---|---|---|
| Comparative | S: 28.8 | j: 8.5 | | | Remainder | Present | 121 |
| method 8B | | | | | | | |
| Conventional | — | — | 28.4 | 6.3 | Remainder | Present | 185 |
| method 8B | | | | | | | |

Pressure sintering process: hot isostatic pressing method

From the results shown in Table 15, it is apparent that the targets produced by the aforementioned methods 64B to 70B of the present invention generated less particles as compared to the target produced by the conventional method 8B which was produced by blending and mixing a Co powder having a 50% particle size of 10 μm, a Cr powder having a 50% particle size of 10 μm, a Pt powder having a 50% particle size of 15 μm, and an TiO₂ powder having a 50% particle size of 3 μm without adding a Cr—Pt binary alloy powder and a Co—Cr binary alloy powder. However, it is apparent that the target produced by the comparative method 8B which was produced using the Cr—Pt binary alloy powder S shown in Table 6 having a composition that was outside the scope of the present invention and the Co—Cr binary alloy powder j shown in Table 7 having a composition that was outside the scope of the present invention generated numerous particles, and thus was not preferable.

### Example 13

The raw material powders were blended so as to give the compositions shown in Table 16 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders. Methods 71B to 79B of the present invention, a comparative method 9B, and a conventional method 9B were conducted as follows. The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies. These hot pressed bodies were cut to produce targets having a diameter of 152.4 mm and a thickness of 3 mm as well as a chemical composition consisting of 10.1 mol % of Cr, 15.6 mol % of Pt, 8.0 mol % of Ta₂O₅ and a remainder containing Co.

Absolute maximum lengths (maximum value of the distance between the two arbitrary points on the periphery of the particle) of the chromium oxide aggregates dispersed in the microstructure of the targets produced by the aforementioned methods 71B to 79B of the present invention, the comparative method 9B, and the conventional method 9B were measured by an EPMA in the same manner as in Example 1. The presence/absence of coarse chromium oxide aggregates having an absolute maximum length of more than 10 μm is shown in Table 16.

Moreover, the targets obtained by the aforementioned methods 71B to 79B of the present invention, the comparative method 9B, and the conventional method 9B were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under the same conditions as those in Example 5. Subsequently, the number of particles attached on the wafer surface and having a size of 1.0 μm or more was counted in the same manner as in Example 5 and the average value of the counts obtained from 25 wafers was calculated. The results are shown in Table 16.

TABLE 16

| | | Composition of raw material powder (% by mass) | | | | | | |
|---|---|---|---|---|---|---|---|---|
| | | Pt—Cr | | | | | Presence/absence | |
| | | binary | | | | | of Cr oxides | Number of |
| | | alloy | | | | | having absolute | particles of |
| | | powder of | | Ta₂O₅ | | | maximum length | 1.0 μm or |
| Type | | Table 6 | Pt powder | powder | Cr powder | Co powder | larger than 10 μm | larger |
| Method of | 71B | A: 10.5 | 28.7 | 18.8 | — | Remainder | Absent | 76 |
| present | 72B | B: 12.3 | 26.9 | | | Remainder | Absent | 45 |
| invention | 73B | C: 14.4 | 24.8 | | | Remainder | Absent | 20 |
| | 74B | D: 16.7 | 22.5 | | | Remainder | Absent | 25 |
| | 75B | E: 19.3 | 19.9 | | | Remainder | Absent | 31 |
| | 76B | F: 22.4 | 16.8 | | | Remainder | Absent | 36 |
| | 77B | G: 26.0 | 13.2 | | | Remainder | Absent | 39 |
| | 78B | H: 30.2 | 9.0 | | | Remainder | Absent | 42 |
| | 79B | I: 35.2 | 4.0 | | | Remainder | Absent | 45 |

| | | | | | | |
|---|---|---|---|---|---|---|
| Comparative | R: 8.9 | 30.3 | | Remainder | Present | 103 |
| method 9B | | | | | | |
| Conventional | — | 31.8 | 7.4 | Remainder | Present | 165 |
| method 9B | | | | | | |

Pressure sintering process: vacuum hot pressing method

From the results shown in Table 16, it is apparent that the targets produced by the aforementioned methods 71B to 79B of the present invention which were produced by blending the Cr—Pt binary alloy powders A to K having a Pt content of 10 to 90 atomic % and a remainder containing Cr as the raw material powders generated less particles as compared to the target produced by the conventional method 9B which was produced by blending and mixing a Co powder having a 50% particle size of 10 μm, a Cr powder having a 50% particle size of 10 μm, a Pt powder having a 50% particle size of 15 μm, and an Ta₂O₅ powder having a 50% particle size of 3 μm without adding a Cr—Pt binary alloy powder. However, it is apparent that the target produced by the comparative method 9B which was produced using the Cr—Pt binary alloy powder R having a composition that was outside the scope of the present invention generated numerous particles, and thus was not preferable.

### Example 14

The Cr—Pt binary alloy powders A to G shown in Table 6, the Co powder, the Pt powder, and the Ta₂O₅ powder were blended so as to give the compositions shown in Table 17 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders. The mixed powders obtained as described above were filled in an SUS container and were subjected to a vacuum degassing treatment under conditions in which the powders were retained at a temperature of 550° C. for 12 hours, and thereafter the mixed powders were vacuum encapsulated by sealing the SUS container. Methods 80B to 88B of the present invention, a comparative method 10B, and a conventional method 10B were conducted as follows. The SUS container filled with the mixed powders was subjected to a hot isostatic pressing process under conditions in which the powders were retained at a temperature of 1,200° C. and a pressure of 100 MPa for 3 hours followed by opening the SUS container to produce hot isostatic pressed bodies having a chemical composition consisting of 13.6 mol % of Cr, 14.6 mol % of Pt, 3.0 mol % of Ta₂O₅ and a remainder containing Co. These hot isostatic pressed bodies were cut to produce targets having a diameter of 152.4 mm and a thickness of 3 mm. The same measurements as those in Example 5 were conducted on the targets obtained by the aforementioned methods 80B to 88B of the present invention, the comparative method 10B, and the conventional method 10B. The results are shown in Table 17.

TABLE 17

| | | Composition of raw material powder (% by mass) | | | | | | |
|---|---|---|---|---|---|---|---|---|
| | | Pt—Cr | | | | | Presence/absence | |
| | | binary | | | | | of Cr oxides | Number of |
| | | alloy | | | | | having absolute | particles of |
| | | powder of | | Ta₂O₅ | | | maximum length | 1.0 μm or |
| Type | | Table 6 | Pt powder | powder | Cr powder | Co powder | larger than 10 μm | larger |
| Method of | 80B | A: 11.2 | 28.5 | 14.9 | — | Remainder | Absent | 72 |
| present | 81B | B: 13.1 | 26.6 | | | Remainder | Absent | 52 |
| invention | 82B | C: 15.3 | 24.4 | | | Remainder | Absent | 43 |
| | 83B | D: 17.8 | 21.9 | | | Remainder | Absent | 76 |
| | 84B | E: 20.6 | 19.1 | | | Remainder | Absent | 32 |
| | 85B | F: 23.9 | 15.8 | | | Remainder | Absent | 44 |
| | 86B | G: 27.7 | 12.0 | | | Remainder | Absent | 47 |
| | 87B | H: 32.2 | 7.5 | | | Remainder | Absent | 51 |
| | 88B | I: 37.6 | 2.1 | | | Remainder | Absent | 50 |

| | | | | | | |
|---|---|---|---|---|---|---|
| Comparative | R: 9.5 | 30.2 | | Remainder | Present | 115 |
| method 10B | | | | | | |
| Conventional | — | 31.8 | 7.9 | Remainder | Present | 172 |
| method 10B | | | | | | |

Pressure sintering process: hot isostatic pressing method

From the results shown in Table 17, it is apparent that the targets produced by the aforementioned methods 80B to 88B of the present invention which were produced by blending the Cr—Pt binary alloy powders A to G having a Pt content of 10 to 90 atomic % and a remainder containing Cr as the raw material powders generated less particles as compared to the target produced by the conventional method 10B which was produced by blending and mixing a Co powder having a 50% particle size of 10 μm, a Cr powder having a 50% particle size of 10 μm, a Pt powder having a 50% particle size of 15 μm, and an Ta₂O₅ powder having a 50% particle size of 3 μm without adding a Cr—Pt binary alloy powder. However, it is apparent that the target produced by the comparative method 10B which was produced using the Cr—Pt alloy powder R having a composition that was outside the scope of the present invention generated numerous particles, and thus was not preferable.

### Example 15

The Cr—Pt binary alloy powders A to J shown in Table 6, the Co—Cr binary alloy powders a to h shown in Table 7, the Co powder, the Pt powder, and the Ta₂O₅ powder were blended so as to give the compositions shown in Table 18 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

Methods 89B to 98B of the present invention, a comparative method 11B, and a conventional method 11B were conducted as follows. The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies having a chemical composition consisting of 14.7 mol % of Cr, 16.7 mol % of Pt, 2.0 mol % of Ta₂O₅ and a remainder containing Co. These hot pressed bodies were cut to produce targets having a diameter of 152.4 mm and a thickness of 3 mm

Absolute maximum lengths (maximum value of the distance between the two arbitrary points on the periphery of the particle) of the chromium oxide aggregates dispersed in the microstructure of the targets produced by the aforementioned methods 89B to 98B of the present invention, the comparative method 11B, and the conventional method 11B were measured by an EPMA. The presence/absence of coarse chromium oxide aggregates having an absolute maximum length of more than 10 μm is shown in Table 18.

Measurements of the absolute maximum length of chromium oxide aggregates using an EPMA were conducted by cutting out samples from the targets produced by the aforementioned methods 89B to 98B of the present invention, the comparative method 11B, and the conventional method 11B, and embedding the sections thereof in a resin to be subjected to a mirror polishing process, and the rest of the procedures were carried out in the same manner as in Example 5.

Moreover, the targets obtained by the aforementioned methods 89B to 98B of the present invention, the comparative method 11B, and the conventional method 11B were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under the same conditions as those in Example 5 to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 18.

TABLE 18

| | | Composition of raw material powder (% by mass) | | | | | | | |
|---|---|---|---|---|---|---|---|---|---|
| | | Cr—Pt | Co—Cr | | | | | Presence/absence | |
| | | binary | binary | | | | | of Cr oxides | Number of |
| | | alloy | alloy | | | | | having absolute | particles of |
| | | powder of | powder of | | Ta₂O₅ | | | maximum length | 1.0 μm or |
| Type | | Table 6 | Table 7 | Pt powder | powder | Cr powder | Co powder | larger than 10 μm | larger |
| Method of | 89B | A: 6.1 | d: 7.6 | 35.0 | 10.1 | — | Remainder | Absent | 68 |
| Present | 90B | B: 7.2 | h: 6.4 | 34.0 | | | Remainder | Absent | 61 |
| invention | 91B | C: 8.4 | a: 9.2 | 32.8 | | | Remainder | Absent | 54 |
| | 92B | D: 9.7 | e: 7.3 | 31.4 | | | Remainder | Absent | 46 |
| | 93B | E: 11.3 | g: 6.7 | 29.9 | | | Remainder | Absent | 37 |
| | 94B | F: 13.1 | b: 8.5 | 28.1 | | | Remainder | Absent | 41 |
| | 95B | G: 15.2 | c: 7.9 | 26.0 | | | Remainder | Absent | 43 |
| | 96B | H: 17.6 | f: 7.0 | 23.5 | | | Remainder | Absent | 49 |
| | 97B | I: 20.6 | b: 8.5 | 20.6 | | | Remainder | Absent | 52 |
| | 98B | J: 24.2 | g: 6.7 | 17.0 | | | Remainder | Absent | 57 |

| | | | | | | | |
|---|---|---|---|---|---|---|---|
| Comparative | R: 5.2 | i: 9.6 | 36.0 | | Remainder | Present | 110 |
| method 11B | | | | | | | |
| Conventional | — | — | 36.8 | 8.7 | Remainder | Present | 201 |
| method11B | | | | | | | |

Pressure sintering process: vacuum hot pressing method

From the results shown in Table 18, it is apparent that the targets produced by the aforementioned methods 89B to 98B of the present invention which were produced by blending the Cr—Pt binary alloy powders shown in Table 6 and the Co—Cr binary alloy powders shown in Table 7 as the raw material powders generated less particles as compared to the target produced by the conventional method 11B which was produced by blending and mixing a Co powder having a 50% particle size of 10 μm, a Cr powder having a 50% particle size of 10 μm, a Pt powder having a 50% particle size of 15 μm, and an TiO₂ powder having a 50% particle size of 3 μm without adding the Cr—Pt binary alloy powder and Co—Cr binary alloy powder shown in Table 18. However, it is apparent that the target produced by the comparative method 11B which was produced using the Co—Cr alloy powder i having a composition that was outside the scope of the present invention shown in Table 7 generated numerous particles which were 1.0 μm or larger, and thus was not preferable.

### Example 16

Methods 99B to 105B of the present invention, a comparative method 12B, and a conventional method 12B were conducted with exactly the same conditions as those in Example 7 except that no Pt powder was used and all the necessary Pt components were included by adding the Cr—Pt binary alloy powders K to Q shown in Table 6, a Ta₂O₅ powder was used as a non-magnetic oxide powder, and that a pressure sintering process was conducted by the same hot isostatic pressing process as in Example 6. The hot isostatic pressed bodies having a composition consisting of 17.5 mol % of Cr, 19.4 mol % of Pt, 3.0 mol % of Ta₂O₅ and a remainder containing Co were produced and these hot isostatic pressed bodies were cut to produce targets having a diameter of 152.4 mm and a thickness of 3 mm. The same measurements as those in Example 5 were conducted on the targets obtained by the aforementioned methods 99B to 105B of the present invention, the comparative method 12B, and the conventional method 12B. The results are shown in Table 19.

TABLE 19

| | | Composition of raw material powder (% by mass) | | | | | | | |
|---|---|---|---|---|---|---|---|---|---|
| | | Pt—Cr | Co—Cr | | | | | Presence/absence | |
| | | binary | binary | | | | | of Cr oxides | Number of |
| | | alloy | alloy | | | | | having absolute | particles of |
| | | powder of | powder of | | Ta₂O₅ | | | maximum length | 1.0 μm or |
| Type | | Table 6 | Table 7 | Pt powder | powder | Cr powder | Co powder | larger than 10 μm | larger |
| Method of | 99B | K: 46.6 | h: 3.7 | — | 13.9 | — | Remainder | Absent | 74 |
| present | 100B | L: 45.3 | g: 5.9 | | | | Remainder | Absent | 63 |
| invention | 101B | M: 44.1 | e: 8.0 | | | | Remainder | Absent | 52 |
| | 102B | N: 43.1 | c: 10.9 | | | | Remainder | Absent | 47 |
| | 103B | O: 42.2 | a: 14.6 | | | | Remainder | Absent | 50 |
| | 104B | P: 41.4 | f: 12.3 | | | | Remainder | Absent | 55 |
| | 105B | Q: 40.7 | d: 14.6 | | | | Remainder | Absent | 59 |

| | | | | | | | |
|---|---|---|---|---|---|---|---|
| Comparative | S: 40.1 | j: 12.9 | | | Remainder | Present | 106 |
| method 12B | | | | | | | |
| Conventional | — | — | 39.6 | 9.5 | Remainder | Present | 192 |
| method 12B | | | | | | | |

Pressure sintering process: hot isostatic pressing method

From the results shown in Table 19, it is apparent that the targets produced by the aforementioned methods 99B to 105B of the present invention generated less particles as compared to the target produced by the conventional method 12B which was produced by blending and mixing a Co powder having a 50% particle size of 10 μm, a Cr powder having a 50% particle size of 10 μm, a Pt powder having a 50% particle size of 15 μm, and an Ta₂O₅ powder having a 50% particle size of 3 μm without adding a Cr—Pt binary alloy powder and a Co—Cr binary alloy powder. However, it is apparent that the target produced by the comparative method 12B which was produced using the Cr—Pt binary alloy powder S shown in Table 6 having a composition that was outside the scope of the present invention and the Co—Cr binary alloy powder j shown in Table 7 having a composition that was outside the scope of the present invention generated numerous particles, and thus was not preferable.

### <Third Aspect>

Co—Cr alloy powders A to J having chemical compositions shown in Table 20 were prepared as raw material powders by a gas atomizing method. Since the Co—Cr alloy powders A to J obtained by the gas atomizing method had a 50% particle size of 95 μm, the Co—Cr alloy powders A to J were classified using a sieve with an aperture size of 45 μm so that the 50% particle size of all the powders measured by a laser diffraction method would be 35 μm. Moreover, a Co powder having a 50% particle size of 10 μm, a Pt powder having a 50% particle size of 15 μm, an SiO₂ powder having a 50% particle size of 3 μm, a TiO₂ powder having a 50% particle size of 3 μm, a Ta₂O₅ powder having a 50% particle size of 3 μm, and a Cr powder having a 50% particle size of 10 μm which were commercially available were prepared.

TABLE 20

| | | | Composition | |
|---|---|---|---|---|
| | | 50% particle | (atomic %) | |
| Type | | size (μm) | Cr | Co |
| Co—Cr | A | 35 | 50 | Remainder |
| alloy | B | | 54 | Remainder |
| powder | C | | 58 | Remainder |
| | D | | 60 | Remainder |
| | E | | 62 | Remainder |
| | F | | 65 | Remainder |
| | G | | 67 | Remainder |
| | H | | 70 | Remainder |
| | I | | 48 | Remainder |
| | J | | 72 | Remainder |

### Example 17

The raw material powders prepared above were blended so as to give the compositions shown in Table 21 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies having the compositions shown in Table 21. These hot pressed bodies were cut to produce targets 1C to 8C of the present invention, comparative targets 1C and 2C, and a conventional target 1C having a diameter of 152.4 mm and a thickness of 3 mm

Absolute maximum lengths (maximum value of the distance between the two arbitrary points on the periphery of the particle) of the chromium oxide aggregates dispersed in the microstructure of the aforementioned targets 1C to 8C of the present invention, the comparative targets 1C and 2C, and the conventional target 1C were measured by an EPMA. The number of chromium oxide aggregates having an absolute maximum length of more than 5 μm and the presence/absence of coarse chromium oxide aggregates having an absolute maximum length of more than 10 μm are shown in Table 21.

Measurements of the absolute maximum length of chromium oxide aggregates using an EPMA were conducted as follows. Samples were cut out from the hot pressed bodies of the aforementioned targets 1C to 8C of the present invention, the comparative targets 1C and 2C, and the conventional target 1C and the sections thereof were embedded in a resin to be subjected to a mirror polishing process. Surface analysis was conducted on the structures of these sections using a field emission EPMA (JXA-8500F manufactured by JEOL Ltd.) to acquire an element mapping image of Cr. Conditions for the surface analysis were an acceleration voltage of 15 kV and an irradiation current of 5×10⁻⁸ A. The Cr mapping image had pixel sizes of 0.5 μm in both X and Y directions and 800 pixels in both X and Y directions. Hence, the analytical range using this Cr mapping image was 400 μm×400 μm. Measuring time was 0.015 seconds and integration frequency was once. This element mapping image of Cr was made to be an image with a contrast and a color tone so that the regions enriched with Cr (that is, chromium oxide aggregates) can be clearly discriminated as much as possible. The obtained element mapping image of Cr was saved as an image file of bitmap format without degrading the image quality and this image was read separately using image processing software (Win Roof manufactured by Mitani Corporation) to binarize the image. Absolute maximum lengths of the regions enriched with Cr as compared to the matrix were measured by image processing. A threshold value was selected for binarization so that the size of the Cr enriched regions did not change from that of the original image. A scale bar indicated on the original element mapping image of Cr by EPMA was used for the calibration of length during measurements. Sampling was conducted from 10 randomly selected points in each target. The composition of chromium oxide aggregates was 30 to 50 atomic % of Cr and 50 to 70 atomic % of oxygen and a remainder containing Co, Pt, and the metal elements constituting the non-magnetic oxide.

Moreover, the aforementioned targets 1C to 8C of the present invention, the comparative targets 1C and 2C, and the conventional target 1C were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under the conditions in which the ultimate vacuum was 5×10⁻⁵ Pa, the electrical power was 800 W in direct current, the Ar gas pressure was 6.0 Pa, the distance between the target and the substrate was 60 mm, and no substrate heating, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 21.

TABLE 21

| | | | | | | | | | | | Number of Cr | Presence/absence | |
|---|---|---|---|---|---|---|---|---|---|---|---|---|---|
| | | | | | | | | | | | oxide aggregates | of Cr oxide | |
| | | Composition of raw material powder (% by mass) | | | | | | | | | having absolute | aggregates | |
| | | Alloy | | | | | Composition | | | | maximum length | having absolute | Number |
| | | powder of | Pt | SiO₂ | Cr | Co | of target (mol %) | | | | larger than 5 μm | maximum length | of |
| Target | | Table 20 | powder | powder | powder | powder | Cr | Pt | SiO₂ | Co | (aggregates/mm²) | larger than 10 μm | particles |
| Present | 1C | A: 14.9 | 39.3 | 7.5 | — | Remainder | 10.8 | 16.2 | 10.0 | Remainder | 355 | Absent | 54 |
| invention | 2C | B: 13.7 | | | | Remainder | | | | Remainder | 152 | Absent | 39 |
| | 3C | C: 12.7 | | | | Remainder | | | | Remainder | 307 | Absent | 50 |
| | 4C | D: 12.3 | | | | Remainder | | | | Remainder | 164 | Absent | 40 |
| | 5C | E: 11.8 | | | | Remainder | | | | Remainder | 294 | Absent | 49 |
| | 6C | F: 11.3 | | | | Remainder | | | | Remainder | 320 | Absent | 51 |
| | 7C | G: 10.9 | | | | Remainder | | | | Remainder | 403 | Absent | 68 |
| | 8C | H: 10.4 | | | | Remainder | | | | Remainder | 459 | Absent | 83 |
| Com- | 1C | I: 15.6 | | | | Remainder | | | | Remainder | 509* | Present | 119 |
| parative | 2C | J: 10.1 | | | | Remainder | | | | Remainder | 532* | Present | 136 |
| target | | | | | | | | | | | | | |

| | | | | | | | |
|---|---|---|---|---|---|---|---|
| Conventional | — | 7.0 | Remainder | Remainder | 621* | Present | 180 |
| target 1C | | | | | | | |

Symbols (*) indicate conditions outside the scope of the present invention.

From the results shown in Table 21, it is apparent that the targets 1C to 8C of the present invention generated less particles as compared to the conventional target 1C. Moreover, it is apparent that the comparative targets 1C and 2C generated numerous particles, and thus were not preferable.

### Example 18

The raw material powders prepared above were blended so as to give the compositions shown in Table 22 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

The obtained mixed powders were filled in an SUS container and were subjected to a vacuum degassing treatment under conditions in which the powders were retained at a temperature of 550° C. for 12 hours, and thereafter the mixed powders were vacuum encapsulated by sealing the SUS container. The SUS container filled with the mixed powders was subjected to a hot isostatic pressing process under conditions in which the powders were retained at a temperature of 1,200° C. and a pressure of 100 MPa for 3 hours followed by opening the SUS container to produce hot isostatic pressed bodies having the compositions shown in Table 22. These hot isostatic pressed bodies were cut to produce targets 9C to 16C of the present invention, comparative targets 3C and 4C, and a conventional target 2C having a diameter of 152.4 mm and a thickness of 3 mm

Absolute maximum lengths (maximum value of the distance between the two arbitrary points on the periphery of the particle) of the chromium oxide aggregates dispersed in the microstructure of the aforementioned targets 9C to 16C of the present invention, the comparative targets 3C and 4C, and the conventional target 2C were measured by an EPMA. The number of chromium oxide aggregates having an absolute maximum length of more than 5 μm and the presence/absence of coarse chromium oxide aggregates having an absolute maximum length of more than 10 μm are shown in Table 19. The method for measuring chromium oxide aggregates was the same as that employed in Example 17.

Moreover, the aforementioned targets 9C to 16C of the present invention, the comparative targets 3C and 4C, and the conventional target 2C were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under the conditions in which the ultimate vacuum was 5×10⁻⁵ Pa, the electrical power was 800 W in direct current, the Ar gas pressure was 6.0 Pa, the distance between the target and the substrate was 60 mm, and no substrate heating, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 22.

TABLE 22

| | | | | | | | | | | | Number of Cr | Presence/absence | |
|---|---|---|---|---|---|---|---|---|---|---|---|---|---|
| | | | | | | | | | | | oxide aggregates | of Cr oxide | |
| | | Composition of raw material powder (% by mass) | | | | | | | | | having absolute | aggregates | |
| | | Alloy | | | | | Composition | | | | maximum length | having absolute | Number |
| | | powder of | Pt | SiO₂ | Cr | Co | of target (mol %) | | | | larger than 5 μm | maximum length | of |
| Target | | Table 20 | powder | powder | powder | powder | Cr | Pt | SiO₂ | Co | (aggregates/mm²) | larger than 10 μm | particles |
| Present | 9C | A: 24.4 | 42.9 | 3.7 | — | Remainder | 18.1 | 18.1 | 5.0 | Remainder | 393 | Absent | 66 |
| inven- | 10C | B: 22.5 | | | | Remainder | | | | Remainder | 184 | Absent | 45 |
| tion | 11C | C: 20.8 | | | | Remainder | | | | Remainder | 340 | Absent | 57 |
| | 12C | D: 20.1 | | | | Remainder | | | | Remainder | 217 | Absent | 48 |
| | 13C | E: 19.4 | | | | Remainder | | | | Remainder | 329 | Absent | 58 |
| | 14C | F: 18.4 | | | | Remainder | | | | Remainder | 345 | Absent | 55 |
| | 15C | G: 17.8 | | | | Remainder | | | | Remainder | 425 | Absent | 75 |
| | 16C | H: 17.0 | | | | Remainder | | | | Remainder | 481 | Absent | 92 |
| Com- | 3C | I: 25.5 | | | | Remainder | | | | Remainder | 522* | Present | 150 |
| parative | 4C | J: 16.5 | | | | Remainder | | | | Remainder | 537* | Present | 173 |
| target | | | | | | | | | | | | | |

| | | | | | | | |
|---|---|---|---|---|---|---|---|
| Conventional | — | 11.4 | Remainder | Remainder | 654* | Present | 195 |
| target 2C | | | | | | | |

Symbols (*) indicate conditions outside the scope of the present invention.

From the results shown in Table 22, it is apparent that the targets 9C to 16C of the present invention, in which the number of chromium oxide aggregates having an absolute maximum length of more than 5 μm in the microstructure was 500 aggregates/mm² or less, generated less particles as compared to the conventional target 2C, in which the number of chromium oxide aggregates having an absolute maximum length of more than 5 μm in the microstructure was more than 500 aggregates/mm² or the chromium oxide aggregates having an absolute maximum length of more than 10 μm were present.

### Example 19

The raw material powders prepared above were blended so as to give the compositions shown in Table 23 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

The obtained mixed powders were filled in a vacuum hot press apparatus and were subjected to a vacuum hot pressing process in a vacuum atmosphere under conditions in which the powders were retained at a temperature of 1,200° C. and a pressure of 15 MPa for 3 hours to produce hot pressed bodies having the compositions shown in Table 23. These hot pressed bodies were cut to produce targets 17C to 24C of the present invention, comparative targets 5C and 6C, and a conventional target 3C having a dimension of 152.4 mm (diameter) and 3 mm (thickness).

Absolute maximum lengths (maximum value of the distance between the two arbitrary points on the periphery of the particle) of the chromium oxide aggregates dispersed in the microstructure of the aforementioned targets 17C to 24C of the present invention, the comparative targets 5C and 6C, and the conventional target 3C were measured by an EPMA. The number of chromium oxide aggregates having an absolute maximum length of more than 5 μm and the presence/absence of coarse chromium oxide aggregates having an absolute maximum length of more than 10 μm are shown in Table 23. The method for measuring chromium oxide aggregates was the same as that employed in Example 17.

Moreover, the aforementioned targets 17C to 24C of the present invention, the comparative targets 5C and 6C, and the conventional target 3C were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under the conditions in which the ultimate vacuum was 5×10⁻⁵ Pa, the electrical power was 800 W in direct current, the Ar gas pressure was 6.0 Pa, the distance between the target and the substrate was 60 mm, and no substrate heating was conducted, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 23.

TABLE 23

| | | | | | | | | | | | Number of Cr | Presence/absence | |
|---|---|---|---|---|---|---|---|---|---|---|---|---|---|
| | | | | | | | | | | | oxide aggregates | of Cr | |
| | | Composition of raw material powder (% by mass) | | | | | | | | | having absolute | oxide aggregates | |
| | | Alloy | | | | | Composition | | | | maximum length | having absolute | Number |
| | | powder of | Pt | TiO₂ | Cr | Co | of target (mol %) | | | | larger than 5 μm | maximum length | of |
| Target | | Table 20 | powder | powder | powder | powder | Cr | Pt | TiO₂ | Co | (aggregates/mm²) | larger than 10 μm | particles |
| Present | 17C | A: 19.3 | 33.9 | 9.2 | — | Remainder | 13.7 | 13.7 | 9.0 | Remainder | 372 | Absent | 63 |
| inven- | 18C | B: 17.8 | | | | Remainder | | | | Remainder | 159 | Absent | 44 |
| tion | 19C | C: 16.5 | | | | Remainder | | | | Remainder | 201 | Absent | 46 |
| | 20C | D: 15.9 | | | | Remainder | | | | Remainder | 336 | Absent | 52 |
| | 21C | E: 15.3 | | | | Remainder | | | | Remainder | 305 | Absent | 55 |
| | 22C | F: 14.6 | | | | Remainder | | | | Remainder | 328 | Absent | 52 |
| | 23C | G: 14.1 | | | | Remainder | | | | Remainder | 412 | Absent | 72 |
| | 24C | H: 13.4 | | | | Remainder | | | | Remainder | 473 | Absent | 90 |
| Com- | 5C | I: 20.2 | | | | Remainder | | | | Remainder | 516* | Present | 141 |
| parative | 6C | J: 13.0 | | | | Remainder | | | | Remainder | 541* | Present | 149 |
| target | | | | | | | | | | | | | |

| | | | | | | | |
|---|---|---|---|---|---|---|---|
| Conventional | — | 9.1 | Remainder | Remainder | 650* | Present | 186 |
| target 3C | | | | | | | |

Symbols (*) indicate conditions outside the scope of the present invention.

From the results shown in Table 23, it is apparent that the aforementioned targets 17C to 24C of the present invention which were produced by blending the Co—Cr alloy powders A to H having a Cr content of 50 to 70 atomic % and a remainder containing Co as the raw material powders generated less particles as compared to the conventional target 3C which was produced by blending and mixing a Co powder having a 50% particle size of 10 μm, a Cr powder having a 50% particle size of 10 μm, a Pt powder having a 50% particle size of 15 μm, and an TiO₂ powder having a 50% particle size of 3 μm without adding a Co—Cr alloy powder. However, it is apparent that the comparative targets 5C and 6C which were produced using the Co—Cr alloy powders I and J having compositions that were outside the scope of the present invention generated numerous particles, and thus were not preferable.

### Example 20

The raw material powders prepared above were blended so as to give the compositions shown in Table 24 and the obtained blended powders were charged in a 10 L container together with a zirconia ball, which was a grinding medium. The atmosphere inside this container was replaced with an Ar gas atmosphere and thereafter, the container was sealed. This container was rotated for 16 hours using a ball mill to prepare mixed powders.

The obtained mixed powders were filled in an SUS container and were subjected to a vacuum degassing treatment under conditions in which the powders were retained at a temperature of 550° C. for 12 hours, and thereafter the mixed powders were vacuum encapsulated by sealing the SUS container. The SUS container filled with the mixed powders was subjected to a hot isostatic pressing process under conditions in which the powders were retained at a temperature of 1,200° C. and a pressure of 100 MPa for 3 hours followed by opening the SUS container to produce hot isostatic pressed bodies having the compositions shown in Table 24. These hot isostatic pressed bodies were cut to produce targets 25C to 32C of the present invention, comparative targets 7C and 8C, and a conventional target 4C having a diameter of 152.4 mm and a thickness of 3 mm

Absolute maximum lengths (maximum value of the distance between the two arbitrary points on the periphery of the particle) of the chromium oxide aggregates dispersed in the microstructure of the aforementioned targets 25C to 32C of the present invention, the comparative targets 7C and 8C, and the conventional target 4C were measured by an EPMA. The number of chromium oxide aggregates having an absolute maximum length of more than 5 μm and the presence/absence of coarse chromium oxide aggregates having an absolute maximum length of more than 10 μm are shown in Table 24. The method for measuring chromium oxide aggregates was the same as that employed in Example 17.

Moreover, the aforementioned targets 25C to 32C of the present invention, the comparative targets 7C and 8C, and the conventional target 4C were degreased using an organic solvent and were subsequently subjected to vacuum drying by being retained under vacuum at 150° C. for 8 hours. Thereafter, the targets were joined with a backing plate made of copper and were mounted on a commercially available sputtering apparatus. A presputtering process was carried out under conditions in which the ultimate vacuum was 5×10⁻⁵ Pa, the electrical power was 800 W in direct current, the Ar gas pressure was 6.0 Pa, the distance between the target and the substrate was 60 mm, and no substrate heating was conducted, to remove the processed layer of the target surface. Then the chamber was temporarily opened to air and the chamber members such as a deposition preventing plate were cleaned. Thereafter, vacuuming was carried out until the above-mentioned vacuum was achieved again. After the vacuuming, a presputtering process was carried out for 30 minutes to remove adsorbed atmospheric components and metal oxide layers, followed by the formation of a magnetic recording film having a thickness of 100 nm on a 4-inch Si wafer. Magnetic recording films having a thickness of 100 nm were formed on a total of 25 pieces of 4-inch Si wafer under the same conditions. With respect to the wafer after the film formation, the number of particles attached on the wafer surface and having a size of 1.0 μm or more was counted using a surface inspection apparatus that was commercially available and the average value of the counts obtained from 25 wafers was calculated. The results are shown in Table 24.

TABLE 24

| | | Composition of raw material powder (% by mass) | | | | | | | | | Number of Cr | Presence/absence | |
|---|---|---|---|---|---|---|---|---|---|---|---|---|---|
| | | Alloy | | | | | | | | | oxide aggregates | of Cr oxide | |
| | | powder | | | | | | | | | having absolute | aggregates having | |
| | | of | | | | | Composition of | | | | maximum length | absolute | Number |
| | | Table | Pt | Ta₂O₅ | Cr | Co | target (mol %) | | | | larger than 5 μm | maximum length | of |
| Target | | 20 | powder | powder | powder | powder | Cr | Pt | Ta₂O₅ | Co | (aggregates/mm²) | larger than 10 μm | particles |
| Present | 25C | A: 15.4 | 34.8 | 18.3 | — | Remainder | 13.4 | 17.3 | 4.0 | Remainder | 377 | Absent | 65 |
| inven- | 26C | B: 14.2 | | | | Remainder | | | | Remainder | 160 | Absent | 46 |
| tion | 27C | C: 13.1 | | | | Remainder | | | | Remainder | 210 | Absent | 50 |
| | 28C | D: 12.7 | | | | Remainder | | | | Remainder | 329 | Absent | 55 |
| | 29C | E: 12.2 | | | | Remainder | | | | Remainder | 299 | Absent | 57 |
| | 30C | F: 11.6 | | | | Remainder | | | | Remainder | 312 | Absent | 55 |
| | 31C | G: 11.2 | | | | Remainder | | | | Remainder | 415 | Absent | 75 |
| | 32C | H: 10.7 | | | | Remainder | | | | Remainder | 452 | Absent | 86 |
| Com- | 7C | I: 16.1 | | | | Remainder | | | | Remainder | 525* | Present | 146 |
| parative | 8C | J: 10.4 | | | | Remainder | | | | Remainder | 539* | Present | 147 |
| target | | | | | | | | | | | | | |

| | | | | | | | |
|---|---|---|---|---|---|---|---|
| Conventional | — | 7.2 | Remainder | Remainder | 635* | Present | 183 |
| target 4C | | | | | | | |

Symbols (*) indicate conditions outside the scope of the present invention.

From the results shown in Table 24, it is apparent that the aforementioned targets 25C to 32C of the present invention which were produced by blending the Co—Cr alloy powders A to H having a Cr content of 50 to 70 atomic % and a remainder containing Co as the raw material powders generated less particles as compared to the conventional target 4C which was produced by blending and mixing a Co powder having a 50% particle size of 10 μm, a Cr powder having a 50% particle size of 10 μm, a Pt powder having a 50% particle size of 15 μm, and an Ta₂O₅ powder having a 50% particle size of 3 μm without adding a Co—Cr alloy powder. However, it is apparent that the comparative targets 7C and 8C which were produced using the Co—Cr alloy powders I and J having compositions that were outside the scope of the present invention generated numerous particles, and thus were not preferable.

1. A method for manufacturing a Co-base sintered alloy sputtering target for formation of a magnetic recording film which is less likely to generate particles, the method comprising:
providing, as raw material powders, a Cr—Co alloy powder consisting of 50 to 70 atomic % of Cr and a remainder containing Co, a Pt powder, a non-magnetic oxide powder, and a Co powder;
blending and mixing the raw material powders together so as to give a chemical composition consisting of 2 to 15 mol % of a nonmagnetic oxide, 3 to 20 mol % of Cr, and 5 to 30 mol % of Pt and a remainder containing Co; and thereafter
subjecting the resulting mixed powder to a pressure sintering process.

2. The method for manufacturing a Co-base sintered alloy sputtering target for the formation of a magnetic recording film which is less likely to generate particles according to claim 1,
wherein the non-magnetic oxide is any one of silicon dioxide, tantalum oxide, titanium oxide, aluminum oxide, magnesium oxide, thorium oxide, zirconium oxide, cerium oxide, and yttrium oxide.

3. The method for manufacturing a Co-base sintered alloy sputtering target for the formation of a magnetic recording film which is less likely to generate particles according to claim 1,
wherein the pressure sintering process is a hot pressing process or a hot isostatic pressing process.

4. A Co-base sintered alloy sputtering target for formation of a magnetic recording film which is less likely to generate particles manufactured by method of claim 1.

5. A method for manufacturing a Co-base sintered alloy sputtering target for formation of a magnetic recording film which is less likely to generate particles, the method comprising:
providing, as raw material powders, a Cr—Pt binary alloy powder consisting of 10 to 90 atomic % of Pt and a remainder containing Cr, a Pt powder, a non-magnetic oxide powder, and a Co powder;
blending and mixing the raw material powders so as to give a chemical composition consisting of 2 to 15 mol % of the non-magnetic oxide, 3 to 20 mol % of Cr, and 5 to 30 mol % of Pt and a remainder containing Co; and thereafter
subjecting the resulting mixed powder to a pressure sintering process.

6. A method for manufacturing a Co-base sintered alloy sputtering target for formation of a magnetic recording film which is less likely to generate particles, the method comprising:
providing, as raw material powders, a Cr—Pt binary alloy powder consisting of 10 to 90 atomic % of Pt and a remainder containing Cr, a Co—Cr binary alloy powder consisting of 50 to 70 atomic % of Cr and a remainder containing Co, a Pt powder, a non-magnetic oxide powder, and a Co powder;
blending and mixing the raw material powders so as to give a chemical composition consisting of 2 to 15 mol % of the non-magnetic oxide, 3 to 20 mol % of Cr, and 5 to 30 mol % of Pt and a remainder containing Co; and thereafter
subjecting the resulting mixed powder to a pressure sintering process.

7. A method for manufacturing a Co-base sintered alloy sputtering target for formation of a magnetic recording film which is less likely to generate particles, the method comprising:
providing, as raw material powders, a Cr—Pt binary alloy powder consisting of 10 to 90 atomic % of Pt and a remainder containing Cr, a Co—Cr binary alloy powder consisting of 50 to 70 atomic % of Cr and a remainder containing Co, a non-magnetic oxide powder, and a Co powder;
blending and mixing the raw material powders so as to give a chemical composition formed of 2 to 15 mol % of the non-magnetic oxide, 3 to 20 mol % of Cr, 5 to 30 mol % of Pt and a remainder containing Co; and thereafter
subjecting the resulting mixed powder to a pressure sintering process.

8. The method for manufacturing a Co-base sintered alloy sputtering target for the formation of a magnetic recording film which is less likely to generate particles according to claim 5,
wherein the non-magnetic oxide is any one of silicon dioxide, tantalum oxide, titanium oxide, aluminum oxide, magnesium oxide, thorium oxide, zirconium oxide, cerium oxide, and yttrium oxide.

9. The method for manufacturing a Co-base sintered alloy sputtering target for the formation of a magnetic recording film which is less likely to generate particles according to claim 5,
wherein the pressure sintering process is a hot pressing process or a hot isostatic pressing process.

10. A Co-base sintered alloy sputtering target for formation of a magnetic recording film which is less likely to generate particles manufactured by the method of claim 5 which is a Co-base sintered alloy sputtering target for the formation of a magnetic recording film having a chemical composition consisting of 2 to 15 mol % of the non-magnetic oxide, 3 to 20 mol % of Cr, and 5 to 30 mol % of Pt and a remainder containing Co,
wherein an absolute maximum length of chromium oxide aggregates dispersed in a microstructure is not more than 10 μm.

11. The Co-base sintered alloy sputtering target for the formation of a magnetic recording film which is less likely to generate particles according to claim 10,
wherein the non-magnetic oxide is any one of silicon dioxide, tantalum oxide, titanium oxide, aluminum oxide, magnesium oxide, thorium oxide, zirconium oxide, cerium oxide, and yttrium oxide.

12. A Co-base sintered alloy sputtering target for formation of a magnetic recording film which is less likely to generate particles having a composition consisting of 2 to 15 mol % of a non-magnetic oxide, 3 to 20 mol % of Cr, and 5 to 30 mol % of Pt and a remainder containing Co and inevitable impurities,
wherein the number of chromium oxide aggregates having an absolute maximum length of more than 5 μm in a microstructure is not more than 500 aggregates/mm².

13. The Co-base sintered alloy sputtering target for the formation of a magnetic recording film which is less likely to generate particles according to claim 12,
wherein chromium oxide aggregates having an absolute maximum length of more than 10 μm are absent in a target microstructure.

14. The method for manufacturing a Co-base sintered alloy sputtering target for the formation of a magnetic recording film which is less likely to generate particles according to claim 6,
wherein the non-magnetic oxide is any one of silicon dioxide, tantalum oxide, titanium oxide, aluminum oxide, magnesium oxide, thorium oxide, zirconium oxide, cerium oxide, and yttrium oxide.

15. The method for manufacturing a Co-base sintered alloy sputtering target for the formation of a magnetic recording film which is less likely to generate particles according to claim 7,
wherein the non-magnetic oxide is any one of silicon dioxide, tantalum oxide, titanium oxide, aluminum oxide, magnesium oxide, thorium oxide, zirconium oxide, cerium oxide, and yttrium oxide.

16. The method for manufacturing a Co-base sintered alloy sputtering target for the formation of a magnetic recording film which is less likely to generate particles according to claim 6,
wherein the pressure sintering process is a hot pressing process or a hot isostatic pressing process.

17. The method for manufacturing a Co-base sintered alloy sputtering target for the formation of a magnetic recording film which is less likely to generate particles according to claim 7,
wherein the pressure sintering process is a hot pressing process or a hot isostatic pressing process.

18. A Co-base sintered alloy sputtering target for formation of a magnetic recording film which is less likely to generate particles manufactured by the method of claim 6 which is a Co-base sintered alloy sputtering target for the formation of a magnetic recording film having a chemical composition consisting of 2 to 15 mol % of the non-magnetic oxide, 3 to 20 mol % of Cr, and 5 to 30 mol % of Pt and a remainder containing Co,
wherein an absolute maximum length of chromium oxide aggregates dispersed in a microstructure is not more than 10 μm.

19. A Co-base sintered alloy sputtering target for formation of a magnetic recording film which is less likely to generate particles manufactured by the method of claim 7 which is a Co-base sintered alloy sputtering target for the formation of a magnetic recording film having a chemical composition consisting of 2 to 15 mol % of the non-magnetic oxide, 3 to 20 mol % of Cr, and 5 to 30 mol % of Pt and a remainder containing Co,
wherein an absolute maximum length of chromium oxide aggregates dispersed in a microstructure is not more than 10 μm.

20. The Co-base sintered alloy sputtering target for the formation of a magnetic recording film which is less likely to generate particles according to claim 6,
wherein the non-magnetic oxide is any one of silicon dioxide, tantalum oxide, titanium oxide, aluminum oxide, magnesium oxide, thorium oxide, zirconium oxide, cerium oxide, and yttrium oxide.

21. The Co-base sintered alloy sputtering target for the formation of a magnetic recording film which is less likely to generate particles according to claim 7,
wherein the non-magnetic oxide is any one of silicon dioxide, tantalum oxide, titanium oxide, aluminum oxide, magnesium oxide, thorium oxide, zirconium oxide, cerium oxide, and yttrium oxide.
